(19) United States
(12) Patent Application Publication
(10) Pub. No.: US 2020/0195121 A1
(43) Pub. Date: Jun. 18, 2020

(54) DYNAMICALLY ADJUSTABLE GATE DRIVER FOR SWITCHING DEVICES AND RELATED METHODS

(71) Applicant: Texas Instruments Incorporated, Dallas, TX (US)

(72) Inventors: Neeraj A. Keskar, Allen, TX (US); Weidong Zhu, East Lyme, CT (US)

(21) Appl. No.: 16/219,349

(22) Filed: Dec. 13, 2018

(51) Int. Cl. H02M 1/08; H02M 3/158; H03K 17/687

(52) U.S. Cl. CPC H02M 1/08; H02M 2001/0009; H03K 17/6871; H02M 3/158

(57) ABSTRACT

Methods, apparatus, systems, and articles of manufacture are disclosed for a dynamically adjustable gate driver for switching devices. An example power switching system includes a gate driver circuit including gate driver segments to adjust a transition time of a switch from a first time to a second time in response to a segment control signal, the transition time corresponding to a time to change a state of the switch, and a controller to obtain a first trip signal to indicate that a voltage exceeds a first threshold, obtain a second trip signal to indicate that the voltage is less than a second threshold, and transmit the segment control signal to the gate driver circuit when the switch is to change state and when the voltage exceeds the first threshold or is less than the second threshold.

### FIELD OF THE DISCLOSURE

This disclosure relates generally to drivers for switching devices and, more particularly, to a dynamically adjustable gate driver for switching devices and related methods.

### BACKGROUND

Power converter circuits are used in various devices to convert input voltages to desired output voltages. For example, a buck converter converts an input voltage into a lower desired output voltage by controlling transistors and/or switches to charge and/or discharge inductors and/or capacitors to maintain the desired output voltage. Power converters may include one or more power switches that may be used to change current paths in the power converters. A driver may be used to enable the power switch(es). To increase the efficiency of such a power converter, the speed of switch transition events (e.g., from off to on) by the driver may be increased to decrease the amount of power lost as a result of the switch transition events.

### BRIEF DESCRIPTION OF THE DRAWINGS

FIG. 1 is a schematic illustration of an example power switching system including an example power switching circuit and example dynamically adjustable gate driver circuits.

FIG. 2A is a schematic illustration of an example dynamically adjustable gate driver included in the example power switching circuit of FIG. 1.

FIG. 2B depicts an example table corresponding to a gate driver pull-down strength of the example dynamically adjustable gate driver circuits of FIG. 1 as a function of an example two-bit value and a value of an example positive current threshold.

FIG. 2C depicts an example table corresponding to a gate driver pull-up strength of the example dynamically adjustable gate driver circuits of FIG. 1 as a function of an example two-bit value and a value of an example negative current threshold.

FIG. 3 depicts an example timing diagram corresponding to operation of a first transistor of the example power switching circuit of FIG. 1.

FIG. 4 depicts an example timing diagram corresponding to operation of a second transistor of the example power switching circuit of FIG. 1.

FIG. 5 depicts a block diagram of an example implementation of the gate driver controller of FIG. 1 to adjust a switching speed of a switching device.

FIG. 6 is a flowchart representative of machine readable instructions that may be executed to implement the example gate driver controller of FIG. 5, and/or, more generally, the example power switching circuit of FIG. 1 to control and/or otherwise manage a switching speed of a switching device.

FIGS. 7A and 7B are flowcharts representative of machine readable instructions that may be executed to implement the example gate driver controller of FIG. 5 to control and/or otherwise manage a switching speed of a switching device.

FIG. 8 is a block diagram of an example processing platform structured to execute the instructions of FIGS. 6-7B to implement the example gate driver controller of FIG. 5.

The figures are not to scale. Instead, the thickness of the layers or regions may be enlarged in the drawings. In general, the same reference numbers will be used throughout the drawing(s) and accompanying written description to refer to the same or like parts.

### DETAILED DESCRIPTION

Power conversion systems or power converters (e.g., buck converters, boost converters, alternating current (AC) to AC converters, direct current (DC) to DC converters, AC-DC converters, etc.) may include power switches (e.g., relays, metal oxide semiconductor field effect transistors (MOSFETs), etc.) that switch currents from one path to another. The power switches are alternately and periodically switched on and off as part of normal operation.

The electrical circuits that control and drive the MOSFET switches are known as gate-driver circuits or simply gate drivers. Among other features, the gate drivers, by means of their output impedance, control a transition time (i.e., a time to change a state of a MOSFET from an ON state to an OFF state or vice-versa). For example, the gate drivers may control a rate or a speed of switch transition (i.e., the rate or speed at which a switch changes from an ON state to an OFF state or vice-versa). In MOSFET-based power converters, the transition rate, the transition time, etc., can correspond to the amount of time necessary to turn on or turn off the MOSFET. For example, a fast gate driver transition time can correspond to less time to turn on or turn off a MOSFET when a voltage is applied to the gate of the MOSFET.

In power converters, the transition rate, the transition time, etc., may directly affect the power loss occurring in the power switches. For example, the faster the switch transition, the lower is the power lost because of the switch transition events. However, due to various reasons, the faster the switch transition, the higher is the electrical stress imposed on the power switch. The switching stress is directly related to the current and voltage being handled by the power switches in normal operation. For example, the higher the magnitude of the handled current, the higher the stress on the power switches during transitions from ON- to OFF-state and vice-versa. Additionally, the electrical stress may be in the form of higher than safe OFF-state voltage across the power switch (e.g., a drain-to-source voltage of a MOSFET) or higher than safe ON-state current (e.g., a drain-to-source current of a MOSFET) in the power switch. The relationship between electrical stress and power loss leads to a design trade-off between lower power loss (i.e., faster switching speed) and lower power switch stress (i.e., slower switching speed).

Power converters have series inductance (e.g., in every wire) and stray capacitance (e.g., in every piece of metal). For example, parasitic capacitances may exist between a drain and a source of a MOSFET. Thus, the inductance and/or capacitance of such systems may cause undesired voltage spikes (e.g., voltage excursions) and/or ringing during current path switching. If a voltage spike is large enough (e.g., above the drain-source breakdown voltage of the transistor), avalanche breakdown can occur inside the transistor. Additionally, if the inductance stores sufficient energy, the transistor breakdown can damage the system by creating a low resistance path through the damaged transistor. As noted above, the switching speed can correspond to the efficiency of a power converter, but fast switching speeds contribute to the magnitude of voltage spikes (e.g., the faster the switching speed the more efficient the system, but the higher the voltage spike).

In several power conversion systems, for reliable operation of the power switches, gate drivers and their output impedance are tuned and/or otherwise fixed so that the switch transition rate is always kept (relatively) slow to limit the electrical stress, which results in additional power loss. However, slow switching speed results in lower power-efficiency of the switching regulator of the power conversion system in steady-state operation, which is an undesired performance characteristic.

In some prior power conversion systems, supply voltage of the gate drivers is adjusted based on the detected current level to improve power efficiency by reducing the gate-charge power losses. However, adjusting the supply voltage of the gate drivers does not directly address switch stresses and is also slow to respond by not making an adjustment upon the current level detection. For example, adjusting the supply voltage does not change the switching speed, which corresponds to changes in switch stresses. In other examples, adjusting the supply voltage is slow to respond because the effects on the power switches based on adjusting the supply voltage occurs over several switching events compared to affecting the power switches prior to every switching event.

Examples disclosed herein provide a dynamically adjustable gate driver to adjust a switching speed of a switching device (e.g., a MOSFET) based on a measured parameter associated with the switching device, such as current. Examples disclosed herein maintain high efficiency in steady-state but reduce voltage excursions by dynamically slowing down the switching transitions of the switching device(s) during pre-determined high-current operations on a per cycle basis. In some disclosed examples, the dynamically adjustable gate driver senses the instantaneous current flowing through one or more of the switching device(s). Based on the sensed current (e.g., a voltage value indicative of a magnitude and a polarity of the current flowing through a switching device), examples disclosed herein dynamically and instantaneously increase turn-on and/or turn-off resistances (e.g., impedances) of the gate drivers during high-current operation.

In some disclosed examples, an adjustment of the gate drivers is based on the magnitude and polarity of the sensed current. For example, in DC-DC buck converters, a first turn-on rate, a first turn-on time, etc., of the low-side MOSFET is slowed down to a second turn-on rate, a second turn-on time, etc., when a measured negative current is less than and/or otherwise satisfies a negative current threshold. In some disclosed examples, the negative current threshold aims to regulate a quantity of current flowing through the low-side MOSFET. Additionally or alternatively, in some disclosed examples, a positive current threshold may aim to regulate a quantity of current flowing through the high-side MOSFET. By reducing the turn-on rate of the low-side MOSFET to the second turn-on rate when the negative current threshold is satisfied, the quantity of current flowing through the low-side MOSFET can be reduced. When the negative current threshold is no longer satisfied, examples disclosed herein restore the turn-on rate of the low-side MOSFET to the first turn-on rate. Advantageously, by restoring the turn-on rate of the low-side MOSFET when the negative current threshold is not satisfied, examples disclosed herein can transition the low-side MOSFET to a steady-state, low-resistance gate driver configuration to yield high-power efficiency.

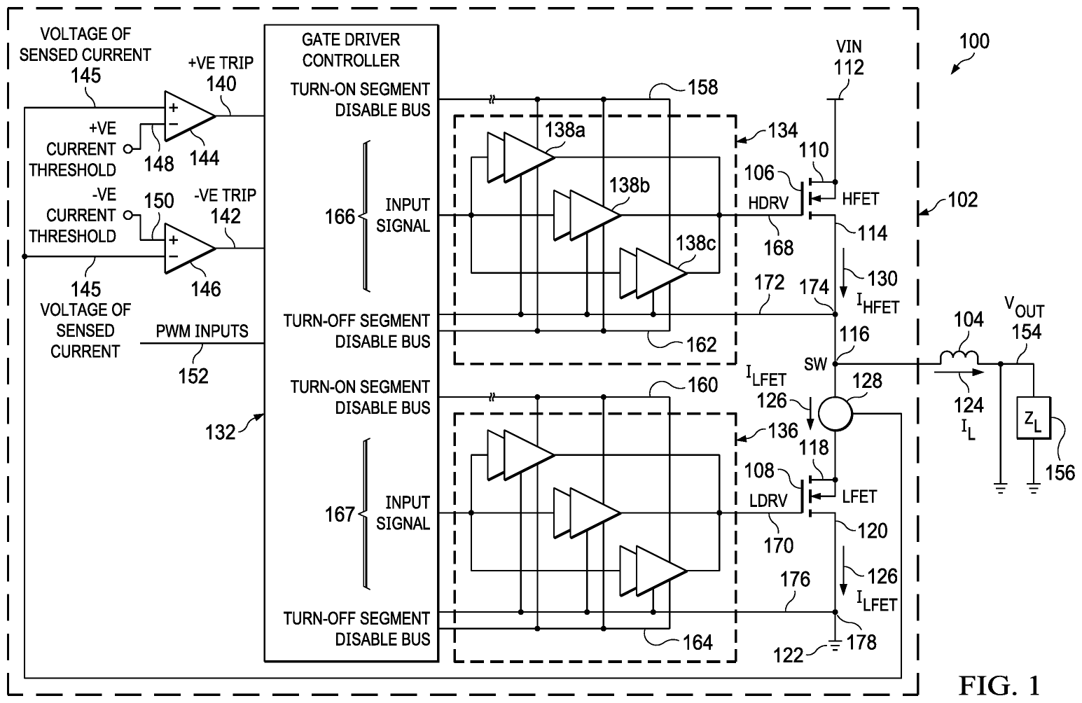

FIG. 1 is a schematic illustration of an example power switching system 100 including an example power switching circuit 102 coupled to an example inductor 104. The power switching circuit 102 of FIG. 1 is a system corresponding to an integrated circuit (IC) chip including one or more electrical circuits. Alternatively, the power switching circuit 102 may be implemented using two or more IC chips. Alternatively, the power switching circuit 102 may be implemented using hardware logic, machine readable instructions, hardware implemented state machines, etc., and/or any combination thereof

In the illustrated example of FIG. 1, the power switching circuit 102 controls speeds of switching transitions of example transistors, including a first example transistor 106 and a second example transistor 108. In the example of FIG. 1, the transistors 106, 108 are N-channel MOSFETs (e.g., power transistors, etc.) that are, for example, utilized as switches. Alternatively, one or both transistors 106, 108 may be P-channel MOSFETs. The first transistor 106 is a high-side MOSFET (HFET), or a high-side switch (i.e., a high-side transistor). The first transistor 106 has a first example drain 110 coupled to an example input voltage (VIN) rail 112 and a first example source 114 coupled to an example switch (SW) node 116. For example, the input voltage rail 112 may correspond to a voltage in a range of 3-16 volts (V). In other examples, the input voltage rail 112 may correspond to a different voltage and/or voltage range.

In FIG. 1, the second transistor 108 is a low-side MOSFET (LFET), or a low-side switch (i.e., a low-side transistor). The second transistor 108 has a second example drain 118 coupled to the first source 114 at the switch node 116 and has a second example source 120 coupled to an example reference rail 122. In the example of FIG. 1, the reference rail 122 is a ground supply. Alternatively, the reference rail 122 may be a negative voltage supply rail.

In the illustrated example of FIG. 1, the power switching circuit 102 controls the speed of switch transition of the transistors 106, 108 based on an example inductor current (IL) 124 flowing through the inductor 104. For example, the power switching circuit 102 may control the transition rate, the transition time, etc., of one or both transistors 106, 108 by measuring current flowing through the first transistor 106, the second transistor 108, etc., which are based on the inductor current 124.

In FIG. 1, the power switching circuit 102 measures current flowing through the second transistor 108, designated by I_{LFET} 126, with an example current sensor 128. For example, the current sensor 128 may be a current sense resistor or a parallel MOSFET, where the parallel MOSFET is matched (e.g., substantially matched within an acceptable tolerance of 1%, 5%, etc.) in characteristics with the second transistor 108. In such examples, the parallel MOSFET can have a gate-source or a gate-drain connectivity identical to that of the second transistor 108. In other examples, the inductor current 124 may be measured with a current sense transformer, or a parallel winding, coupled to the inductor 104. In yet other examples, the current sensor 128 may be coupled elsewhere, such as between the first source 114 and the switch node 116 (e.g., to measure current flowing through the first transistor 106 designated by I_{HFET} 130) or between the second source 120 and the reference rail 122 (e.g., to measure I_{LFET} 126). In other examples, the current sensor 128 may not be in-circuit and/or otherwise included in the power switching circuit 102. For example, the current sensor 128 may be a Hall effect sensor or other type of transducer.

In FIG. 1, the power switching circuit 102 includes an example gate driver controller 132 to modify a switching speed of one or both transistors 106, 108 by adjusting an output impedance of one or both example gate drivers 134, 136 based on sensed current. In FIG. 1, the gate driver controller 132 is a controller. Alternatively, the gate driver controller 132 may be implemented using hardware logic, machine readable instructions, hardware implemented state machines, etc., and/or any combination thereof. In FIG. 1, the gate drivers 134, 136 are gate driver circuits including one or more example gate driver segments 138a-c, including a first example gate driver segment 138a, a second example gate driver segment 138b, and a third example gate driver segment 138c. The gate drivers 134, 136 include a first example gate driver 134 and a second example gate driver 136.

Respective ones of the gate driver segments 138a-c of the gate drivers 134, 136 can be disabled or enabled to adjust an output impedance to respective ones of the transistors 106, 108. For example, each of the gate driver segments 138a-c can be treated and/or otherwise viewed as pull-up or pull-down resistances. If only a first one of the gate driver segments 138a-c of the first gate driver 134 is enabled, then the pull-down resistance is corresponding to that of a single segment (e.g., a resistance of R). When two 2 segments are enabled, the pull-down resistance is the parallel combination of two segments (e.g., a resistance corresponding to a parallel combination of 2 R's and, thus, giving a total pull-up and pull-down resistance of R/2). In such examples, the parallel combination of 2 R's (e.g., R/2) generates a lower output impedance to cause a stronger driving strength when compared to a higher output impedance associated with a single segment (e.g., R). Accordingly, when one of the gate driver segments 138a-c is enabled, a corresponding increase occurs in a driving strength of the gate drivers 134, 136. Conversely, when one of the gate driver segments 138a-c is disabled, a corresponding decrease occurs in the driving strength of the gate drivers 134, 136.

In FIG. 1, the first gate driver 134 is a high-side dynamically adaptive gate driver, or a segmented high-side dynamically adaptive gate driver, which changes an output impedance to the first transistor 106 based on sensed current (e.g., a magnitude and/or a polarity of the inductor current 124, I_{LFET} 126, I_{HFET} 130, etc.). In FIG. 1, the first gate driver 134 includes three gate driver segments 138a-c. Alternatively, the first gate driver 134 may include fewer or more than three of the gate driver segments 138a-c. In FIG. 1, the second gate driver 136 is a low-side dynamically adaptive gate driver, or a segmented low-side dynamically adaptive gate driver, which changes an output impedance to the second transistor 108 based on a value associated with the sensed current (e.g., a voltage indicative of a magnitude and/or a polarity of the sensed current). In FIG. 1, the second gate driver 136 includes three of the gate driver segments 138a-c. Alternatively, the second gate driver 136 may include fewer or more than three of the gate driver segments 138a-c.

In the illustrated example of FIG. 1, the gate driver controller 132 obtains input(s) including example trip signals 140, 142 including a first example trip signal (+ve Trip) 140 and a second example trip signal (-ye Trip) 142 from example comparators 144, 146 including a first example comparator 144 and a second example comparator 146. In FIG. 1, the comparators 144, 146 are voltage comparators. For example, the current sensor 128 may convert an electrical current value corresponding to I_{LFET} 126 (e.g., a value corresponding to a magnitude and/or a polarity of I_{LFET} 126) to an example voltage 145 representative of the magnitude and polarity of I_{LFET} 126. The voltage 145 of the sensed current corresponding to I_{LFET} 126 is provided to the comparators 144, 146. The comparators 144, 146 may compare the voltage 145 to example current thresholds 148, 150 including a first example current threshold (+ve current threshold) 148 and a second example current threshold (−ye current threshold) 150. Alternatively, the comparators 144, 146 may be any other type of electrical (signal) comparator. In FIG. 1, the first current threshold 148 is a positive current threshold. In FIG. 1, the second current threshold 150 is a negative current threshold.

Although two of the comparators 144, 146 are shown, fewer or more than two of the comparators 144, 146 may be used by the power switching circuit 102. In FIG. 1, the first and second current thresholds 148, 150 are stored in memory. For example, the first and second current thresholds 148, 150 may correspond to voltage values stored in memory of the gate driver controller 132, memory external to the gate driver controller 132, or in memory external to the power switching circuit 102. In other examples, the first and second current thresholds 148, 150 may be determined by means of a pin configuration by a user of the power switching circuit 102.

In FIG. 1, the first comparator 144 compares the voltage 145 to the first current threshold 148 and generates and/or otherwise asserts a high signal (e.g., a voltage signal corresponding to a digital one) for the first trip signal 140 when the voltage 145 is greater than the first current threshold 148. For example, the first comparator 144 may generate a high signal when the first comparator 144 determines that (1) a first value of the voltage 145 is indicative of I_{LFET} 126 having a positive polarity and a magnitude of 10 amps (A), is greater than (2) a second value, where the second value is a voltage indicative of the first current threshold 148 having a positive polarity and a magnitude of 8 A. In other examples, the first comparator 144 generates a low signal (e.g., a voltage signal corresponding to a digital zero) for the first trip signal 140 when the voltage 145 is less than the first current threshold 148.

In FIG. 1, the second comparator 146 compares the voltage 145 to the second current threshold 150 and generates and/or otherwise asserts a high signal for the second trip signal 142 when the voltage 145 is less than the second current threshold 150. For example, the second comparator 146 may generate a high signal when the second comparator 146 determines that (1) a third value of the voltage 145 is indicative of I_{LFET} 126 having a negative polarity and a magnitude of −6 A, is less than (2) a fourth value, where the fourth value is a voltage indicative of the second current threshold 150 having a negative polarity and a magnitude of −4 A. In other examples, the second comparator 146 generates a low signal for the second trip signal 142 when the voltage 145 is greater than the second current threshold 150.

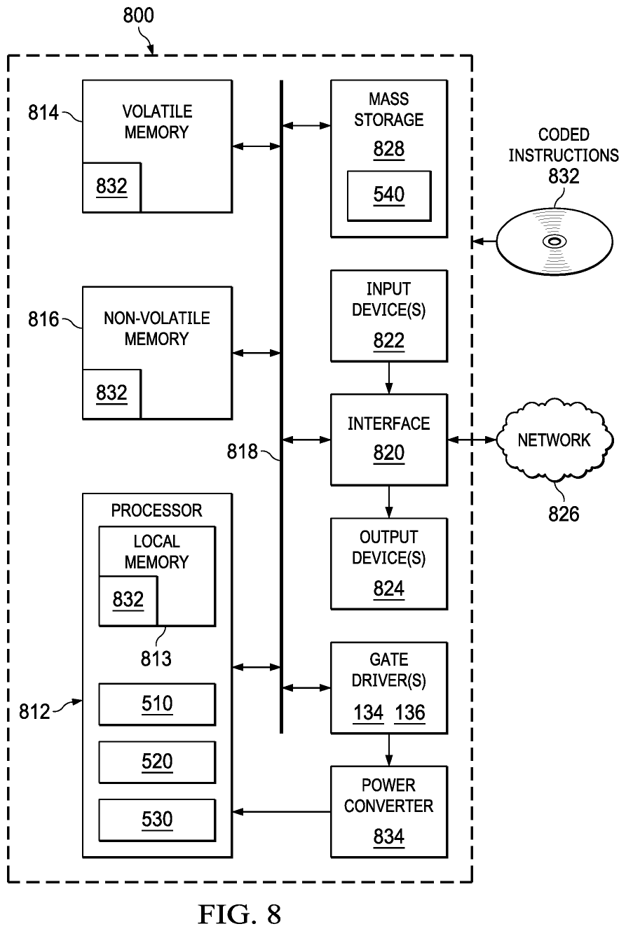

In the illustrated example of FIG. 1, the gate driver controller 132 controls and/or otherwise operates the gate drivers 134, 136 based on at least one of the first trip signal 140, the second trip signal 142, or example pulse-width modulation (PWM) inputs 152. In FIG. 1, the PWM inputs 152 correspond to one or more PWM signals from an external device (e.g., a controller) to the power switching circuit 102. For example, the PWM inputs 152 correspond to control signals to maintain and/or otherwise regulate an example output voltage (Vout) 154 to an example load (ZL) 156. In some examples, the load 156 is a processor. For example, the load 156 may be one or more central processing units (CPUs). In such examples, the load 156 may correspond to a server including one or more CPUs, or any other computing device (e.g., a laptop, a mobile device, a desktop computer, etc.) including one or more CPUs, etc. For example, the load 156 may correspond to the processor 812 of FIG. 8. Additionally or alternatively, the power switching circuit 102 may be electrically in circuit with a buck converter, a boost converter, a buck-boost converter, etc., and/or a combination thereof to maintain and/or otherwise regulate the output voltage 154.

In FIG. 1, the gate driver controller 132 controls the switching speed of one or both transistors 106, 108 by selecting ones of the gate driver segments 138a-c using example turn-on segment disable buses 158, 160, example turn-off segment disable buses 162, 164, and/or example input signals 166, 167. In some examples, each of the gate driver segments 138a-c have equal driving strength. For example, the gate driver controller 132 may proportionally reduce the turn-off rate, increase the transition time, etc., of the first transistor 106 by disabling one or more of the gate driver segments 138a-c of the first gate driver 134. In other examples, the gate driver controller 132 may proportionally reduce the turn-on rate, increase the transition time, etc., of the second transistor 108 by disabling one or more of the gate driver segments 138a-c of the second gate driver 136. Alternatively, in other examples, ones of the gate driver segments 138a-c may have different driving strengths from each other.

In FIG. 1, the input signals 166, 167 include a first input signal 166 and a second input signal 167. In FIG. 1, the input signals 166, 167 are control signals (e.g., input control signals) that are operative to enable (i.e., turn on) or disable (i.e., turn off) the gate drivers 134, 136, the transistors 106, 108, etc. For example, the gate driver controller 132 may generate the first input signal 166 to direct the first gate driver 134 to output a high value for a first example gate control signal (HDRV) 168. In other examples, the gate driver controller 132 may generate the first input signal 166 to direct the first gate driver 134 to output a low value for the first gate control signal 168. In yet other examples, the gate driver controller 132 can generate the second input signal 167 to direct the second gate driver 136 to output a high value or a low value for a second example gate control signal (LDRV) 170.

In FIG. 1, the turn-on segment disable buses 158, 160 are control signals (e.g., segment control signals). The turn-on segment disable buses 158, 160 include a first turn-on segment disable bus 158 and a second turn-on segment disable bus 160. The first turn-on segment disable bus 158 controls a transition time to change from a first state (e.g., an OFF state) to a second state (e.g., an ON state) of the first transistor 106 by adjusting a slope of a rising edge of the first gate control signal 168 (e.g., a turn-on rate). For example, the first turn-on segment disable bus 158 may adjust the transition time from a first transition time to a second transition time by adjusting the slope of the rising edge, where the first transition time is a first quantity of time that is less than a second quantity of time associated with the second transition time. The second turn-on segment disable bus 160 controls a transition time to change from the first state to the second state of the second transistor 108 by adjusting a slope of a rising edge of the second gate control signal 170. For example, the second turn-on segment disable bus 160 may adjust the transition time from a third transition time to a fourth transition time by adjusting the slope of the rising edge, where the third transition time is a third quantity of time that is less than a fourth quantity of time associated with the fourth transition time.

In FIG. 1, the turn-off segment disable buses 162, 164 are control signals (e.g., segment control signals). The turn-off segment disable buses 162, 164 include a first turn-off segment disable bus 162 and a second turn-off segment disable bus 164. The first turn-off segment disable bus 162 controls a transition time from the second state to the first state of the first transistor 106 by adjusting a slope of a falling edge of the first gate control signal 168 (e.g., a turn-off rate). For example, the first turn-off segment disable bus 162 may adjust the transition time from the second transition time to the first transition time by adjusting the slope of the falling edge. The second turn-off segment disable bus 164 controls a transition time from the second state to the first state of the second transistor 108 by adjusting a slope of a falling edge of the second gate control signal 170. For example, the second turn-off segment disable bus 164 may adjust the transition time from the fourth transition time to the third transition time by adjusting the slope of the falling edge.

In some examples, the gate driver controller 132 adjusts a transition time from an OFF state to an ON state of the first and second transistors 106, 108 by disabling or enabling ones of the gate driver segments 138a-c using the first turn-on segment disable buses 158, 160. For example, the gate driver controller 132 may decrease a transition time from the OFF state to the ON state of the second transistor 108 by enabling or turning on ones of the three gate driver segments 138a-c of the second gate driver 136. In other examples, the gate driver controller 132 may increase a transition time from the OFF state to the ON state of the second transistor 108 by disabling ones of the three gate driver segments 138a-c of the second gate driver 136.

In some examples, the gate driver controller 132 adjusts a transition time from the ON state to the OFF state of the first and second transistors 106, 108 by disabling or enabling ones of the gate driver segments 138a-c using the turn-off segment disable buses 162, 164. For example, the gate driver controller 132 may increase a transition time from the ON state to the OFF state of the first transistor 106 by disabling or turning off ones of the three gate driver segments 138a-c of the first gate driver 134. In other examples, the gate driver controller 132 may decrease a transition time from the ON state to the OFF state of the first transistor 106 by enabling one or more of the three gate driver segments 138a-c of the first gate driver 134.

Further shown in FIG. 1 is a first example return rail 172 coupled to the gate driver controller 132 and each of the gate driver segments 138a-c of the first gate driver 134. In FIG. 1, the first return rail 172 is depicted as being coupled to the first source 114, the switch node 116, and the second drain 118 at a first example return node 174. In FIG. 1, a second example return rail 176 is coupled to the gate driver controller 132 and each of the gate driver segments 138a-c of the second gate driver 136. In FIG. 1, the second return rail 176 is depicted as being coupled to the second source 120 and the reference rail 122 at a second example return node 178.

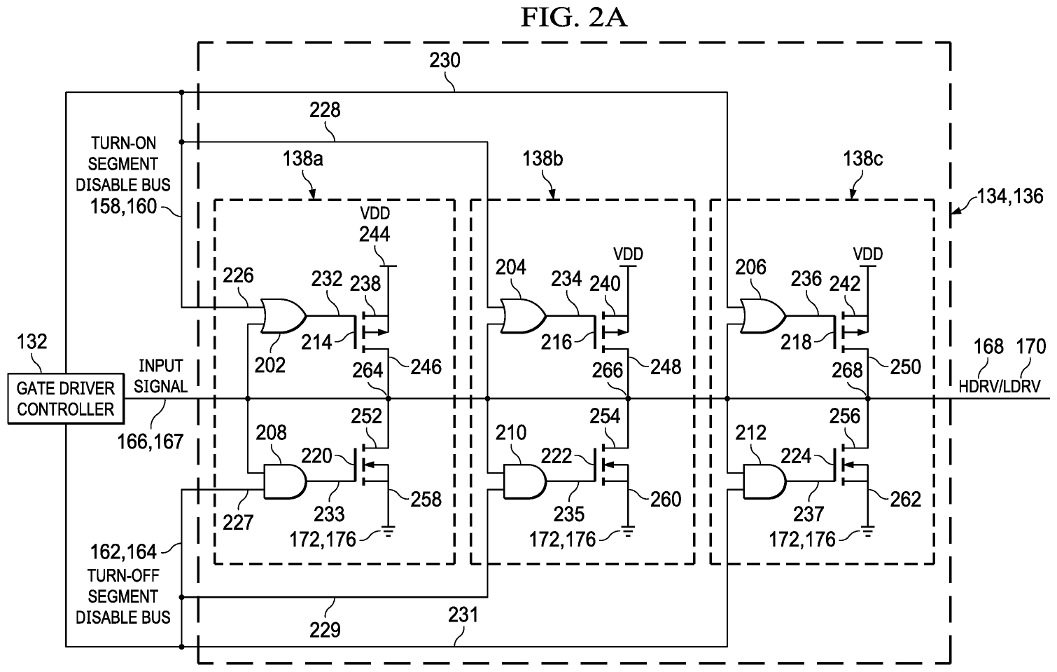

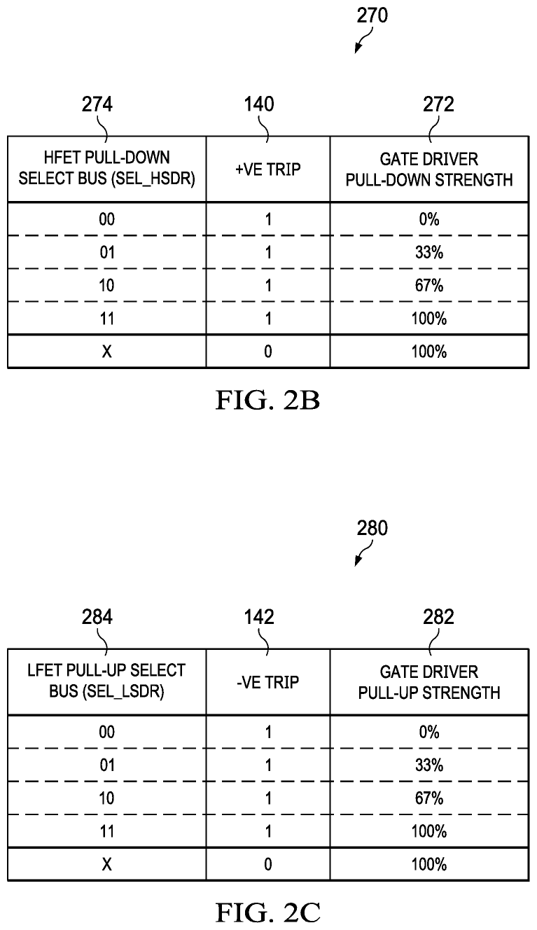

FIG. 2A is a schematic illustration of the gate drivers 134, 136 included in the power switching circuit 102 of FIG. 1. Although only one of the gate drivers 134, 136 is depicted in FIG. 2A, the example schematic illustration of FIG. 2A is applicable to both gate drivers 134, 136 of FIG. 1. In FIG. 2A, the gate driver 134, 136 includes three of the gate driver segments 138a-c. Additionally or alternatively, the gate driver 134, 136 of FIG. 2A may include fewer or more than two of the gate driver segments 138a-c. For example, the gate driver 134, 136 may include one of the gate driver segments 138a-c, two or more gate driver segments 138a-c, etc. In FIG. 2A, the gate drivers 134, 136 include first example logic gates 202, 204, 206, second example logic gates 208, 210, 212, first example transistors 214, 216, 218, and second example transistors 220, 222, 224.

In the illustrated example of FIG. 2A, the first logic gates 202, 204, 206 are OR logic gates and include a first OR logic gate 202, a second OR logic gate 204, and a third OR logic gate 206. In FIG. 2A, the second logic gates 208, 210, 212 are AND gates and include a first AND logic gate 208, a second AND logic gate 210, and a third AND logic gate 212. Additionally or alternatively, the gate drivers 134, 136 may include fewer or more than three OR gates and/or fewer or more than three AND gates.

In FIG. 2A, the first transistors 214, 216, 218 are switches. In FIG. 2A, the first transistors 214, 216, 218 are P-channel MOSFETs and include a first P-channel MOSFET 214, a second P-channel MOSFET 216, and a third P-channel MOSFET 218. In FIG. 2A, the second transistors 220, 222, 224 are switches. In FIG. 2A, the second transistors 220, 222, 224 are N-channel MOSFETs and include a first N-channel MOSFET 220, a second N-channel MOSFET 222, and a third N-channel MOSFET 224. Additionally or alternatively, the gate drivers 134, 136 may include fewer or more than three P-channel MOSFETs and/or fewer or more than three N-channel MOSFETs. In FIG. 2A, the gate driver controller 132 turns off or disables one(s) of the gate driver segments 138a-c when both the P-channel transistor and the N-channel transistor included in the one(s) of the gate driver segments 138a-c are turned off. In FIG. 2A, the gate driver controller 132 turns on or enables the one(s) of the gate driver segments 138a-c when either the P-channel transistor or the N-channel transistor included in the one(s) of the gate driver segments 138a-c are turned on.

In the illustrated example of FIG. 2A, the first logic gates 202, 204, 206 are each coupled to a respective one of the input signals 166, 167 of FIG. 1 and a respective one of example turn-on segment disable bus connections 226, 228, 230 of the turn-on segment disable bus 158, 160 including a first turn-on segment disable bus connection 226, a second turn-on segment disable bus connection 228, and a third turn-on segment disable bus connection 230. In FIG. 2A, the turn-on segment disable bus 158, 160 includes at least the three separate connections 226, 228, 230 (e.g., three electrical conductors not connected to each other). Each of the turn-on segment disable bus connections 226, 228, 230 can correspond to a control signal. The turn-on segment disable bus connections 226, 228, 230 facilitate transmission of segment disable signals, such as turn-on segment disable signals. For example, the gate driver controller 132 of FIG. 1 may generate and transmit a high signal for a first turn-on segment disable bus signal to the first OR logic gate 202 via the first turn-on segment disable bus connection 226, a low signal for a second turn-on segment disable bus signal to the second OR logic gate 204 via the second turn-on segment disable bus connection 228, and a high signal for a third turn-on segment disable bus signal to the third OR logic gate 206 via the third turn-on segment disable bus connection 230. In other examples, the gate driver controller 132 may generate and transmit different signals (e.g., high signals, low signals, etc.) to the OR logic gates 202, 204, 206.

In the illustrated example of FIG. 2A, the second logic gates 208, 210, 212 are each coupled to a respective one of the input signals 166, 167 of FIG. 1 and a respective one of example turn-off segment disable bus connections 227, 229, 231 of the turn-off segment disable bus 162, 164 including a first turn-off segment disable bus connection 227, a second turn-off segment disable bus connection 229, and a third turn-off segment disable bus connection 231. In FIG. 2A, the turn-off segment disable bus 162, 164 includes at least the three separate connections 227, 229, 231 (e.g., three electrical conductors not connected to each other). Each of the turn-off segment disable bus connections 227, 229, 231 can correspond to a control signal. The turn-off segment disable bus connections 227, 229, 231 facilitate transmission of segment disable signals, such as turn-off segment disable signals. For example, the gate driver controller 132 may generate and transmit a high signal for a first turn-off segment disable bus signal to the first AND logic gate 208 via the first turn-off segment disable bus connection 227, a low signal for a second turn-off segment disable bus signal to the second AND logic gate 210 via the second turn-off segment disable bus connection 229, and a high signal for a third turn-off segment disable bus signal to the third AND logic gate 212 via the third turn-off segment disable bus connection 231. In other examples, the gate driver controller 132 may generate and transmit different signals (e.g., high signals, low signals, etc.) to the AND logic gates 208, 210, 212.

In FIG. 2A, the OR logic gates 202, 204, 206 are each coupled to first example gates (i.e., gate terminals) 232, 234, 236 of the first transistors 214, 216, 218 including a first gate 232, a second gate 234, and a third gate 236. For example, the first OR logic gate 202 is coupled to the first gate 232, the second OR logic gate 204 is coupled to the second gate 234, and the third OR logic gate 206 is coupled to the third gate 236. In FIG. 2A, first example sources (i.e., source terminals) 238, 240, 242 of the first transistors 214, 216, 218 including a first source 238, a second source 240, and a third source 242 are each coupled to an example voltage rail (VDD) 244. For example, the voltage rail 244 may be a +3.3 V rail, a +5 V rail, etc. Alternatively, the voltage rail 244 may correspond to any other voltage.

In FIG. 2A, the AND logic gates 208, 210, 212 are each coupled to second example gates (i.e., gate terminals) 233, 235, 237 of the second transistors 220, 222, 224 including a fourth gate 233, a fifth gate 235, and a sixth gate 237. For example, the first AND logic gate 208 is coupled to the fourth gate 233, the second AND logic gate 210 is coupled to the fifth gate 235, and the third AND logic gate 212 is coupled to the sixth gate 237.

In FIG. 2A, first example drains 246, 248, 250 including a first drain 246, a second drain 248, and a third drain 250 are each coupled to second example drains 252, 254, 256 of the second transistors 220, 222, 224 including a fourth drain 252, a fifth drain 254, and a sixth drain 256. For example, the first drain 246 of the first P-channel MOSFET 214 is coupled to the fourth drain 252 of the first N-channel MOSFET 220, the second drain 248 of the second P-channel MOSFET 216 is coupled to the fifth drain 254 of the second N-channel MOSFET 222, and the third drain 250 of the third P-channel MOSFET 218 is coupled to the sixth drain 256 of the third N-channel MOSFET 224. In the example of the first gate driver 134, example second sources 258, 260, 262 are coupled to the first return rail 172 of FIG. 1. In the example of the second gate driver 136, the second sources 258, 260, 262 are coupled to the second return rail 176 of FIG. 1.

In the illustrated example of FIG. 2A, outputs of each of the gate driver segments 138a-c are coupled to each to generate either the first gate control signal 168 or the second gate control signal 170. In FIG. 2A, the first gate driver segment 138a generates a first output at a first example output node 264. In FIG. 2A, the second gate driver segment 138b generates a second output at a second example output node 266. In FIG. 2A, the third gate driver segment 138c generates a third output at a third example output node 268. In FIG. 2A, the first output node 264, the second output node 266, and the third output node 268 are coupled to each other to generate the first gate control signal 168 in the example of the first gate driver 134 or generate the second gate control signal 170 in the example of the second gate driver 136.

FIG. 2B depicts an example table 270 corresponding to example pull-down strengths 272 of the first gate driver 134 of FIGS. 1 and 2A as a function of an example HFET pull-down select bus (SEL_HSDR) 274 and a value of the first trip signal 140 of FIG. 1. In FIG. 2B, the HFET pull-down select bus 274 is a 2-bit selection bus. Alternatively, the HFET pull-down selection bus 274 may be a selection bus having a different number of bits. In some examples, additional positive current thresholds to the first current threshold 140 can be used to increase a resolution and/or granularity of changes in the pull-down strengths 272 of the first gate driver 134.

The HFET pull-down selection bus 274 of FIG. 2B determines a pull-down strength (e.g., a driver strength) of the first gate driver 134 when the first trip signal 140 is asserted. In some examples, the HFET pull-down select bus 274 is included in the gate driver controller 132 of FIGS. 1 and 2A. For example, the gate driver controller 132 may be programmed by transmitting a 2-bit value of “10” on the HFET pull-down select bus 274.

In the illustrated example of FIG. 2B, the 2-bit value of “10” corresponds to a pull-down strength of 67% for the first gate driver 134, where a pull-down strength of 100% corresponds to a maximum pull-down strength. In such examples, when the first trip signal 140 is asserted (e.g., +ve Trip=1), the gate driver controller 132 can disable one of the gate driver segments 138a-c of the first gate driver 134 to reduce the pull-down strength from 100% to 67% based on the 2-bit value of “10”. For example, the gate driver controller 132 may disable the first gate driver segment 138a of the first gate driver 134. In such examples, the gate driver controller 132 can reduce the speed at which the first gate driver 134 turns off the first transistor 106 by reducing the pull-down strength of the first gate driver 134. By disabling the first gate driver segment 138a (e.g., by asserting the first input signal 166 and asserting the first turn-off segment disable bus 162 on the first turn-off segment disable bus connection 227), the gate driver controller 132 can increase the impedance associated with the second transistors 220, 222, 224 of FIG. 2A which, in turn, can cause the reduction in speed of turning off the first transistor 106. When the first trip signal 140 is no longer asserted (e.g., +ve Trip=0), the gate driver controller 132 may enable the first gate driver segment 138a (e.g., by generating a low signal on the first turn-off segment disable bus 162 on the first turn-off segment disable bus connection 227) to restore the pull-down strength of the first gate driver 134 to 100%.

FIG. 2C depicts an example table 280 corresponding to example pull-up strengths 282 of the second gate driver 136 of FIGS. 1 and 2A as a function of an example LFET pull-up select bus (SEL_LSDR) 284 and a value of the second trip signal 142. In FIG. 2C, the LFET pull-up select bus 284 is a 2-bit selection bus. Alternatively, the LFET pull-up selection bus 284 may be a selection bus having a different number of bits. In some examples, additional negative current thresholds to the second current threshold 142 can be used to increase a resolution and/or granularity of changes in the pull-up strengths 282 of the second gate driver 136.

The LFET pull-up selection bus 284 determines a pull-up strength (e.g., a driver strength) of the second gate driver 136 when the second trip signal 142 is asserted. In some examples, the LFET pull-down select bus 284 is included in the gate driver controller 132. For example, the gate driver controller 132 may be programmed by transmitting a 2-bit value of “01” on the LFET pull-up select bus 284. The 2-bit value of “01” corresponds to a pull-up strength of 33% for the second gate driver 136, where a pull-up strength of 100% corresponds to a maximum pull-up strength. In such examples, when the second trip signal 142 is asserted (e.g., −ye Trip=1), the gate driver controller 132 can disable two of the gate driver segments 138a-c of the second gate driver 136 to reduce the pull-up strength from 100% to 33% based on the 2-bit value of “01”. For example, the gate driver controller 132 may disable the first and second gate driver segments 138a-b of the second gate driver 136. In such examples, the gate driver controller 132 can reduce the speed at which the second gate driver 136 turns on the second transistor 108 by reducing the pull-up strength of the second gate driver 136. By disabling the first and second gate driver segments 138a-b, the gate driver controller 132 can increase the impedance associated with the first transistors 214, 216, 218 of FIG. 2A which, in turn, can cause the reduction in speed of turning on the second transistor 108. When the second trip signal 142 is no longer asserted (e.g., −ye Trip=0), the gate driver controller 132 may enable the first and second gate driver segments 138a-b to restore the pull-up strength of the second gate driver 136 to 100%.

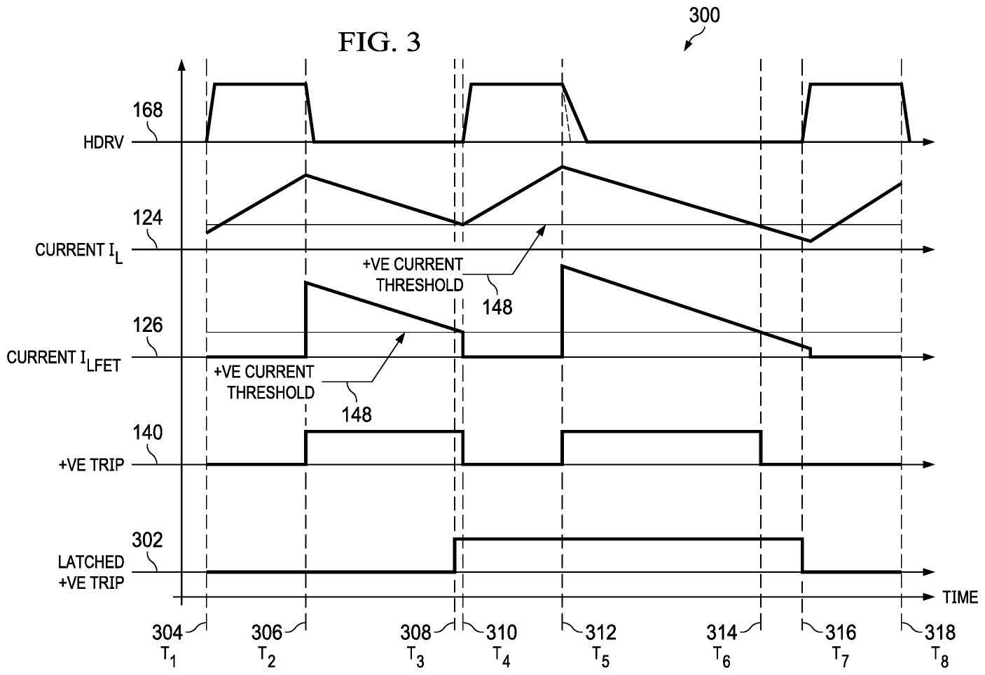

FIG. 3 depicts an example timing diagram 300 corresponding to operation of the first transistor 106 of the power switching circuit 102 of FIG. 1. The timing diagram 300 of FIG. 3 corresponds to operation of the power switching circuit 102 when I_{LFET} 126 of FIG. 1 flowing through the second transistor 108 is greater than the first current threshold 148. The timing diagram 300 of FIG. 3 depicts example waveforms for the first gate control signal 168, the inductor current 124, I_{LFET} 126, and the first trip signal 140 of FIG. 1. Further depicted in the timing diagram 300 of FIG. 3 are the first current threshold 148 of FIG. 1 and a first example latched trip signal (Latched +ve Trip) 302. In FIG. 3, the first latched trip signal 302 is a latched positive current trip signal. For example, the first latched trip signal 302 can be generated by the gate driver controller 132 of FIG. 1. In such examples, the first latched trip signal 302 can be generated internally and used by the gate driver controller 132 to adjust turn-on and/or turn-off (slew) rates of the first and second transistors 106, 108.

In the illustrated example of FIG. 3, the first transistor 106 of FIG. 1 is in the ON state from a first example time (T₁) 304 until a second example time (T₂) 306. For example, the gate driver controller 132 of FIG. 1 can generate a high signal for the first input signal 166 to the first gate driver 134 of FIGS. 1-2 prior to the first time 304 to direct the first gate driver 134 to generate a low signal for the first gate control signal 168. In such examples, the gate driver controller 132 can generate a low signal for the first input signal 166 at the first time 304 until the second time 306 to direct the first gate driver 134 to generate a high signal for the first gate control signal 168. At the second time 306, the gate driver controller 132 can generate a high signal for the first input signal 166 to direct the first gate driver 134 to generate a low signal for the first gate control signal 168.

In FIG. 3, at the second time 306, the first transistor 106 is transitioning from the ON state to the OFF state and the second transistor 108 of FIG. 1 is transitioning from the OFF state to the ON state. For example, the gate driver controller 132 may determine that the first transistor 106 is transitioning from the ON state to the OFF state based on the gate driver controller 132 transitioning from generating a low signal to a high signal for the first input signal 166. In other examples, the gate driver controller 132 may determine that the second transistor 108 is transitioning from the OFF state to the ON state based on the gate driver controller 132 transitioning from generating a high signal to a low signal for the second input signal 167.

At the second time 306, I_{LFET} 126 begins flowing through the second transistor 108 at a level or a value greater than the first current threshold 148. For example, the first comparator 144 of FIG. 1 may obtain a measurement of current (e.g., the voltage 145 indicative of I_{LFET} 126) from the current sensor 128 of FIG. 1 that is greater than a value (e.g., a voltage value) corresponding to the first current threshold 148. In such examples, at the second time 306, the first comparator 144 can generate a high signal for the first trip signal 140 as depicted in FIG. 3.

In the illustrated example of FIG. 3, the second transistor 108 transitions from the ON state to the OFF state at a third example time (T₃) 308. For example, the first and the second transistors 106, 108 are in the OFF state from the third time 308 until a fourth example time (T₄) 310 to prevent cross-conduction or shoot through between the first and second transistors 106, 108.

In FIG. 3, the first latched trip signal 302 is asserted high at the third time 308 when the first trip signal 140 is asserted high and the second gate control signal 170 of FIG. 1 is turned off in response to the first gate control signal 168 transitioning from off to on and/or otherwise is turned ON. By asserting the first latched trip signal 302 high at the third time 308, the gate driver controller 132 determines to adjust a turn-off rate of the first transistor 106 from a first turn-off rate to a second turn-off rate, where the first turn-off rate is faster than the second turn-off rate. For example, a first transition time of the first transistor 106 (e.g., a time to switch from the ON state to the OFF state) is adjusted to a second transition time, where the first transition time is less than the second transition time.

In FIG. 3, the first trip signal 140 remains high from the second time until the fourth time 310, at which I_{LFET} 126 goes below the first current threshold 148. For example, at the fourth time 310, the first comparator 144 may detect that the voltage 145 is less than the first current threshold 148.

In FIG. 3, the first transistor 106 transitions to the ON state at the fourth time 310 and transitions to the OFF state at a fifth example time (T₅) 312. For example, at the fourth time 310, the gate driver controller 132 may generate a low signal for the first input signal 166 of FIG. 1 to direct the first gate driver 134 to generate a high signal for the first gate control signal 168. At the fifth time 312, the gate driver controller 132 generates a high signal for the first input signal 166 to direct the first gate driver 134 to generate a low signal for the first gate control signal 168.

At the fifth time 312, the gate driver controller 132 disables one(s) of the gate driver segments 138a-c of the first gate driver 134 to adjust the switching speed of the first transistor 106 when the first latched trip signal 302 is asserted high. For example, the gate driver controller 132 may generate and transmit a low signal to one or more of the second logic gates 208, 210, 212 of FIG. 2A via the first turn-off segment disable bus 162 of FIGS. 1-2 to reduce the speed of transition from the ON state to the OFF state of the first transistor 106. By transmitting the low signal to one or more of the second logic gates 208, 210, 212, corresponding one(s) of the second transistors 220, 222, 224 of FIG. 2A are turned off. By turning off corresponding one(s) of the second transistors 220, 222, 224, the (total) impedance associated with the second transistors 220, 222, 224 is increased and, thus, reduces the speed at which the first gate driver 134 turns off the first transistor 106. The reduction in the speed at which the first gate driver 134 turns off the first transistor 106 is represented in FIG. 3 as a difference between the dashed line and the solid line of the falling edge of the first gate control signal 168 at the fifth time 312.

In FIG. 3, at the fifth time 312, the first trip signal 140 is asserted high when I_{LFET} 126 goes above the first current threshold 148. The first trip signal 140 remains high from the fifth time 312 until a sixth example time (T₆) when I_{LFET} 126 goes below the first current threshold 148. The first latched trip signal 302 remains high from the third time 308 until a seventh example time (T₇) 316 when I_{LFET} 126 is below the first current threshold 148 at the next turn-off of the second transistor 108 (e.g., the subsequent transition of the second gate control signal 170 from the ON state to the OFF state after the third time 308). In response to the first latched trip signal 302 being asserted low at the seventh time 316, the gate driver controller 132 generates and transmits (1) a high signal as the first input signal 166 and (2) high signals to the second logic gates 208, 210, 212 of the first gate driver 134 to turn on the second transistors 220, 222, 224 of FIG. 2A to restore the transition rate of the first transistor 106 to the unadjusted and/or otherwise maximum transition rate at an eighth example time (T₈) 318. Advantageously, by adjusting and/or otherwise reducing the turn-off transition rate of the first transistor 106 at the fifth time 312, the gate driver controller 132 can improve the reliability and increase the operating lifetime of the first transistor 106 by reducing the switching stress (e.g., over-voltage) across the first transistor 106 when the first transistor 106 transitions to the OFF state.

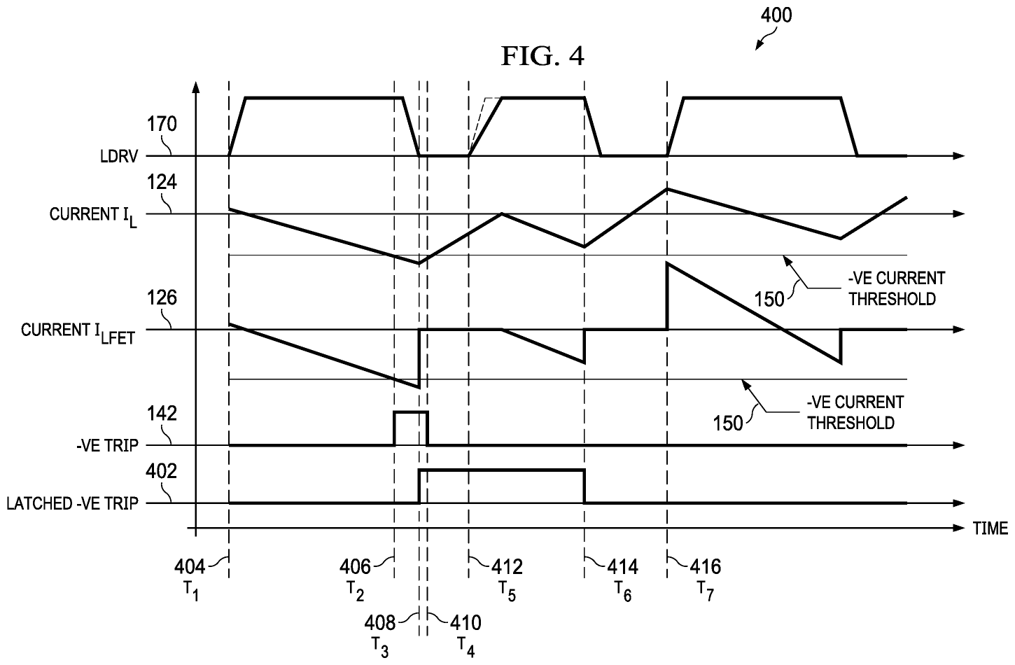

FIG. 4 depicts an example timing diagram 400 corresponding to operation of the second transistor 108 of the power switching circuit 102 of FIG. 1. The timing diagram 400 of FIG. 4 corresponds to operation of the power switching circuit 102 when I_{LFET} 126 flowing through the second transistor 108 is less than the second current threshold 150. The timing diagram 400 of FIG. 4 depicts example waveforms for the second gate control signal 170, the inductor current 124, the I_{LFET} current 126, and the second trip signal 142 of FIG. 1. Further depicted in the timing diagram 400 of FIG. 4 are the second current threshold 150 of FIG. 1 and a second example latched trip signal (Latched −ve Trip) 402. In FIG. 4, the second latched trip signal 402 is a latched negative current trip signal. For example, the second latched trip signal 402 can be generated by the gate driver controller 132 of FIG. 1. In such examples, the second latched trip signal 402 can be generated internally and used by the gate driver controller 132 to adjust turn-on and/or turn-off (slew) rates of the first and second transistors 106, 108.

In the illustrated example of FIG. 4, the second transistor 108 of FIG. 1 is in the ON state at a first example time (T₁) 404. For example, the gate driver controller 132 of FIG. 1 can generate and transmit a low signal for the second input signal 167 of FIG. 1 to the second gate driver 136 of FIG. 1 to direct the second gate driver 136 to generate a high signal for the second gate control signal 170 at the first time 404.

In FIG. 4, at a second example time (T₂) 406, I_{LFET} 126 goes below the second current threshold 150 which, in turn, causes the second trip signal 142 to be asserted high. For example, the second comparator 146 of FIG. 1 may compare the voltage 145 to the second current threshold 150 and assert a high signal for the second trip signal 142 when the voltage 145 is less than the second current threshold 150. In FIG. 4, the second latched trip signal 402 is not asserted high until a turn-off of the second gate control signal 170 at a third example time (T₃) 408. For example, the second latched trip signal 402 is asserted high when the first trip signal 140 is asserted high and the second gate control signal 170 is asserted low. In FIG. 4, the second trip signal 142 remains high from the second time 406 until a fourth example time (T₄) 410.

By asserting the second latched trip signal 402 high at the third time 408, the gate driver controller 132 determines to adjust a turn-on rate of the second transistor 108 from a first turn-on rate to a second turn-on rate, where the first turn-on rate is faster than the second turn-on rate. For example, a first transition time of the second transistor 108 (e.g., a time to switch from the OFF state to the ON state) is adjusted to a second transition time, where the first transition time is less than the second transition time. In FIG. 4, at a fifth example time (T₅) 412, the gate driver controller 132 generates a low signal for the second input signal 167 of FIG. 1 to direct the second gate driver 136 to generate a high signal for the second gate control signal 170.

At the fifth time 412, the gate driver controller 132 disables one(s) of the gate driver segments 138a-c of the second gate driver 136 of FIGS. 1-2 to adjust the switching speed of the second transistor 108 when the second latched trip signal 402 is asserted high. For example, the gate driver controller 132 may generate a low signal for the second input signal 167. In such examples, the gate driver controller 132 can generate and transmit a high signal to one or more of the first logic gates 202, 204, 206 of FIG. 2A via the second turn-on segment disable bus 160 of FIGS. 1-2 to reduce the speed of transition from the OFF state to the ON state of the second transistor 108. By transmitting the high signal to one or more of the first logic gates 202, 204, 206, corresponding one(s) of the first transistors 214, 216, 218 of FIG. 2A are turned off. By turning off corresponding one(s) of the first transistors 214, 216, 218, the (total) impedance associated with the second transistors 220, 222, 224 is increased and, thus, reduces the speed at which the second gate driver 136 turns on the second transistor 108.

In FIG. 4, the second latched trip signal 402 remains high from the third time 408 until a sixth example time (T₆) 414 when the I_{LFET} current 126 is above the second current threshold 150 at the subsequent turn-off of the second gate control signal 170. In response to the second latched trip signal 402 being asserted low at the sixth time 414, the gate driver controller 132 generates and transmits low signals to the first logic gates 202, 204, 206 to turn on the first transistors 214, 216, 218 of FIG. 2A to restore the transition rate of the second transistor 108 to the unadjusted and/or otherwise maximum transition rate at a seventh example time (T₇) 416. By adjusting and/or otherwise reducing the turn-on transition rate of the second transistor 108 at the fifth time 412, the gate driver controller 132 can improve the reliability and increase the operating lifetime of the first transistor 106 by reducing the switching stress (e.g., over-voltage) across the first transistor 106 when the second transistor 108 transitions to the ON state.

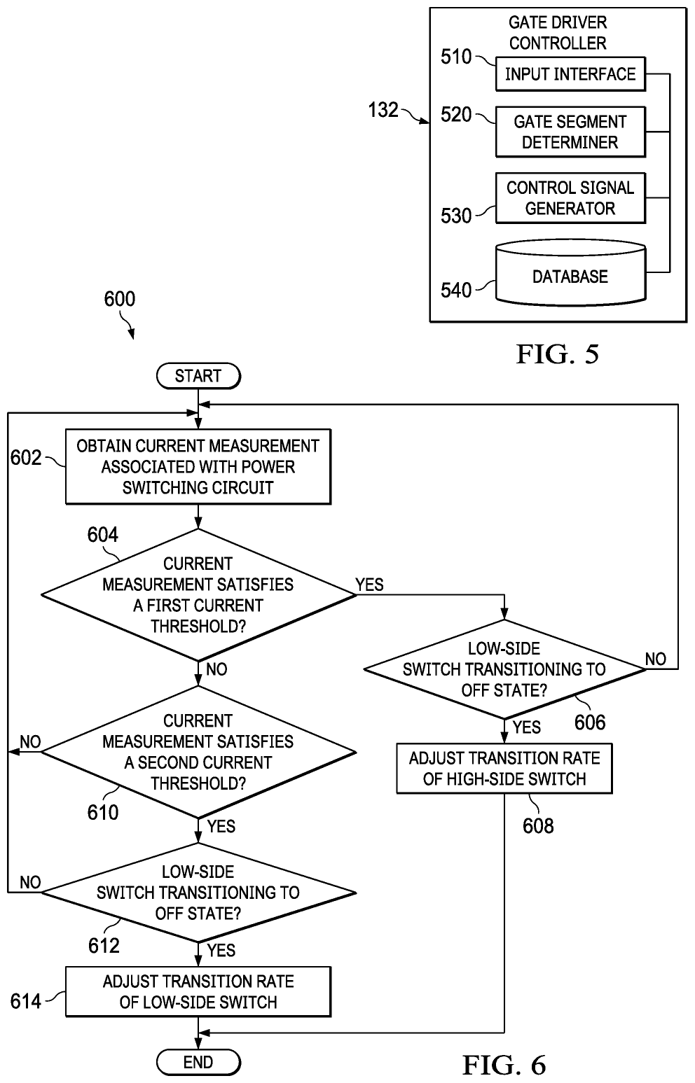

FIG. 5 depicts a block diagram of an example implementation of the gate driver controller 132 of FIG. 1 to adjust a switching speed of the first and second transistors 106, 108 of FIG. 1 based on a measured parameter associated with the power switching circuit 102 of FIG. 1. The gate driver controller 132 obtains sensor measurement determinations associated with the power switching circuit 102 of FIG. 1 and determines one(s) of the gate driver segments 138a-c to select to adjust a turn-on and/or a turn-off rate of the first transistor 106 and/or the second transistor 108 of FIG. 1 based on the obtained sensor measurement determinations. In some examples, the gate driver controller 132 disables one(s) of the gate driver segments 138a-c to reduce a turn-on and/or a turn-off rate of the first transistor 106 and/or the second transistor 108. In some examples, the gate driver controller 132 enables one(s) of the gate driver segments 138a-c to increase a turn-on and/or a turn-off rate of the first transistor 106 and/or the second transistor 108. In the illustrated example of FIG. 5, the gate driver controller 132 includes an example input interface 510, an example gate segment determiner 520, an example control signal generator 530, and an example database 540.

In FIG. 5, the gate driver controller 132 includes the input interface 510 to obtain input(s) including trip signals, PWM inputs, etc. In some examples, the input interface 510 includes means to receive the first trip signal 140 of FIG. 1, the second trip signal 142 of FIG. 1, and/or the PWM inputs 152 of FIG. 1. In other examples, the input interface 510 includes means to receive and/or otherwise obtain sensor measurements. For example, the input interface 510 may obtain the voltage 145 of FIG. 1.

In some examples, the input interface 510 includes means to determine whether an input indicates that a measured parameter satisfies a threshold. For example, the input interface 510 may determine that a high signal for the first trip signal 140 indicates that the voltage 145 is greater than the first current threshold 148. In such examples, the input interface 510 can determine that the voltage 145 is satisfying the first current threshold 148. In other examples, the input interface 510 may determine that a high signal for the second trip signal 142 indicates that the voltage 145 is less than the second current threshold 150.

In the illustrated example of FIG. 5, the gate driver controller 132 includes the gate segment determiner 520 to select one or more of the gate driver segments 138a-c of FIG. 1 to adjust and/or otherwise modify. In some examples, the gate segment determiner 520 includes means to select one(s) of the gate driver segments 138a-c by querying a look-up table. For example, the gate segment determiner 520 may query a look-up table included in the database 540 to determine that the first gate driver segment 138a is to be turned off when adjusting the turn-off rate of the first transistor 106. In other examples, the gate segment determiner 520 can be pre-programmed to select respective one(s) of the gate driver segments 138a-c to adjust when the first latched trip signal 302 of FIG. 3 or the second latched trip signal 402 of FIG. 4 is asserted high. In yet other examples, the gate segment determiner 520 may select one or more of the gate driver segments 138a-c to turn on or off based on a value of the voltage 145, a rate of change associated with the voltage 145, etc.

In some examples, the gate segment determiner 520 includes means to select one or more of the gate driver segments 138a-c of the first gate driver 134 to adjust. For example, the gate segment determiner 520 may determine to select the first gate driver segment 138a of the first gate driver 134 to turn off to reduce a turn-off rate of the first transistor 106 of FIG. 1. In other examples, the gate segment determiner 520 may determine to select the first gate driver segment 138a of the first gate driver 134 to turn on to increase the turn-off rate of the first transistor 106. In yet other examples, the gate segment determiner 520 includes means to adjust a turn-on rate of the first transistor 106 by selecting to adjust one or more of the gate driver segments 138a-c of the first gate driver 134.

In some examples, the gate segment determiner 520 includes means to select one or more of the gate driver segments 138a-c of the second gate driver 136 to adjust. For example, the gate segment determiner 520 may determine to select the first gate driver segment 138a of the second gate driver 136 to turn off to reduce a turn-on rate of the second transistor 108 of FIG. 1. In other examples, the gate segment determiner 520 may determine to select the first gate driver segment 138a of the second gate driver 136 to turn on to increase the turn-on rate of the second transistor 108. In yet other examples, the gate segment determiner 520 includes means to adjust a turn-off rate of the second transistor 108 by selecting to adjust one or more of the gate driver segments 138a-c of the second gate driver 136.

In the illustrated example of FIG. 5, the gate driver controller 132 includes the control signal generator 530 to generate control signal(s) to control, direct, and/or otherwise manage switching events or operations of the first transistor 106 and/or the second transistor 108 of FIG. 1. In some examples, the control signal generator 530 includes means to generate the first input signal 166 to turn on or turn off the first gate driver 134. In some examples, the control signal generator 530 includes means to generate the second input signal 167 to turn on or turn off the second gate driver 136.

In some examples, the control signal generator 530 includes means to adjust a state of one or more of the gate driver segments 138a-c of FIG. 1. For example, the control signal generator 530 may decrease a turn-off rate of the first transistor 106 by generating and transmitting (1) a high signal for the first input signal 166 and (2) a low signal to one(s) of the second logic gates 208, 210, 212 via the first turn-off segment disable bus 162. In other examples, the control signal generator 530 may decrease a turn-on rate of the second transistor 108 by generating and transmitting (1) a low signal for the second input signal 167 and (2) a high signal to one(s) of the first logic gates 202, 204, 206 via the second turn-on segment disable bus 160.

In the illustrated example of FIG. 5, the gate driver controller 132 includes the database 540 to record and/or otherwise store data. The database 540 of FIG. 5 includes the first current threshold 148 and the second current threshold 150 of FIG. 1. The database 540 can be implemented by a volatile memory (e.g., a Synchronous Dynamic Random Access Memory (SDRAM), Dynamic Random Access Memory (DRAM), RAMBUS Dynamic Random Access Memory (RDRAM), etc.) and/or a non-volatile memory (e.g., flash memory). The database 540 can additionally or alternatively be implemented by one or more double data rate (DDR) memories, such as DDR, DDR2, DDR3, mobile DDR (mDDR), etc. The database 540 can additionally or alternatively be implemented by one or more mass storage devices such as hard disk drive(s), compact disk drive(s) digital versatile disk drive(s), etc.

While in the illustrated example of FIG. 5 the database 540 is illustrated as a single database, the database 540 can be implemented by any number and/or type(s) of databases. Furthermore, the data stored in the database 540 can be in any data format such as, for example, binary data, comma delimited data, tab delimited data, structured query language (SQL) structures, etc.

While an example manner of implementing the gate driver controller 132 of FIGS. 1-2 is illustrated in FIG. 5, one or more of the elements, processes, and/or devices illustrated in FIG. 5 may be combined, divided, re-arranged, omitted, eliminated, and/or implemented in any other way. Further, the example input interface 510, the example gate segment determiner 520, the example control signal generator 530, the example database 540, and/or, more generally, the example gate driver controller 132 of FIGS. 1-2 may be implemented by hardware, software, firmware, and/or any combination of hardware, software, and/or firmware. Thus, for example, any of the example input interface 510, the example gate segment determiner 520, the example control signal generator 530, the example database 540, and/or, more generally, the example gate driver controller 132 could be implemented by one or more analog or digital circuit(s), logic circuits, programmable processor(s), programmable controller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)). When reading any of the apparatus or system claims of this patent to cover a purely software and/or firmware implementation, at least one of the example input interface 510, the example gate segment determiner 520, the example control signal generator 530, and/or the example database 540 is/are hereby expressly defined to include a non-transitory computer readable storage device or storage disk such as a memory, a digital versatile disk (DVD), a compact disk (CD), a Blu-ray disk, etc., including the software and/or firmware. Further still, the example gate driver controller 132 of FIGS. 1-2 may include one or more elements, processes, and/or devices in addition to, or instead of, those illustrated in FIG. 5, and/or may include more than one of any or all of the illustrated elements, processes, and devices. As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

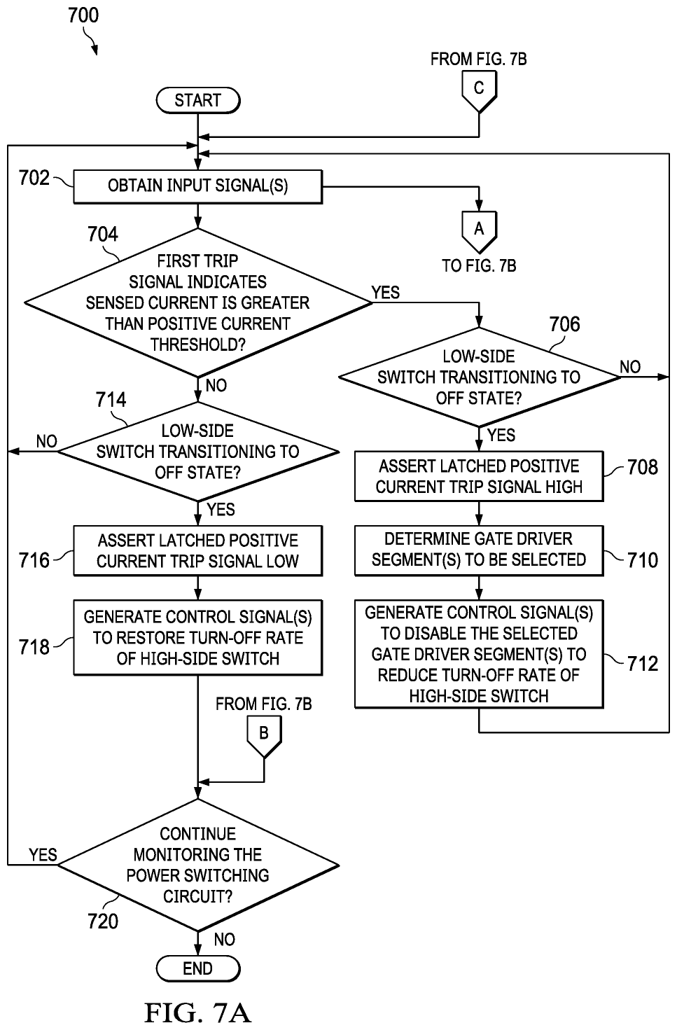

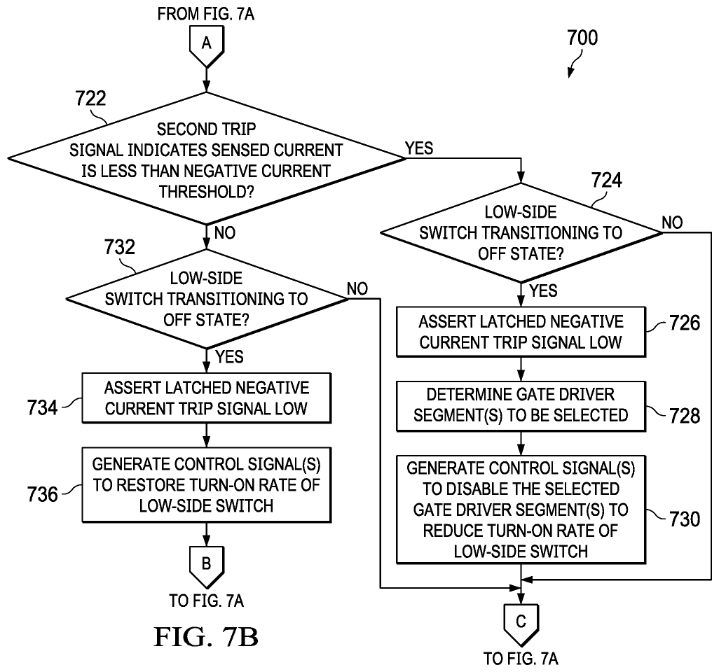

Flowcharts representative of example hardware logic, machine readable instructions, hardware implemented state machines, and/or any combination thereof for implementing the gate driver controller 132 of FIGS. 1-2 and 5, and/or, more generally, the power switching circuit 102 of FIG. 1 is shown in FIGS. 6-7B. The machine readable instructions may be an executable program or portion of an executable program for execution by a computer processor such as the processor 812 shown in the example processor platform 800 discussed below in connection with FIG. 8. The program may be embodied in software stored on a non-transitory computer readable storage medium such as a CD-ROM, a floppy disk, a hard drive, a DVD, a Blu-ray disk, or a memory associated with the processor 812, but the entire program and/or parts thereof could alternatively be executed by a device other than the processor 812 and/or embodied in firmware or dedicated hardware. Further, although the example program is described with reference to the flowcharts illustrated in FIGS. 6-7B, many other methods of implementing the example gate driver controller 132, and/or, more generally, the power switching circuit 102 may alternatively be used. For example, the order of execution of the blocks may be changed, and/or some of the blocks described may be changed, eliminated, or combined. Additionally or alternatively, any or all of the blocks may be implemented by one or more hardware circuits (e.g., discrete and/or integrated analog and/or digital circuitry, an FPGA, an ASIC, a comparator, an operational-amplifier (op-amp), a logic circuit, etc.) structured to perform the corresponding operation without executing software or firmware.

As mentioned above, the example processes of FIGS. 6-7B may be implemented using executable instructions (e.g., computer and/or machine readable instructions) stored on a non-transitory computer and/or machine readable medium such as a hard disk drive, a flash memory, a read-only memory, a compact disk, a digital versatile disk, a cache, a random-access memory, and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc. may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, and (7) A with B and with C. As used herein in the context of describing structures, components, items, objects and/or things, the phrase “at least one of A and B” is intended to refer to implementations including any of (1) at least one A, (2) at least one B, and (3) at least one A and at least one B. Similarly, as used herein in the context of describing structures, components, items, objects and/or things, the phrase “at least one of A or B” is intended to refer to implementations including any of (1) at least one A, (2) at least one B, and (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, and (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, and (3) at least one A and at least one B.

FIG. 6 is a flowchart representative of example machine readable instructions 600 which may be executed to implement the gate driver controller 132 of FIGS. 1-2 and 5, and/or, more generally, the power switching circuit 102 of FIG. 1 to control and/or otherwise manage switching speeds of the first transistor 106 and the second transistor 108 of FIG. 1. The machine readable instructions 600 of FIG. 6 begin at block 602, at which the power switching circuit 102 obtains a current measurement associated with the power switching circuit 102. For example, the current sensor 128 of FIG. 1 may convert a measurement of I_{LFET} 126 into the voltage 145. In such examples, the current sensor 128 can transmit the voltage 145 to the first comparator 144 and the second comparator 146 of FIG. 1 for evaluation.

At block 604, the power switching circuit 102 determines whether the current measurement satisfies a first current threshold. For example, the first comparator 144 of FIG. 1 may compare the voltage 145 to the first current threshold 148 and generate the first trip signal 140 based on the comparison. In such examples, the first comparator 144 can generate a high signal for the first trip signal 140 when the voltage 145 is greater than the first trip signal 140.

If, at block 604, the power switching circuit 102 determines that the current measurement satisfies the first current threshold, then, at block 606, the power switching circuit 102 determines whether a low-side switch is transitioning to an OFF state. For example, the gate driver controller 132 may determine that the second transistor 108 of FIG. 1 is transitioning to the OFF state based on generating a high signal for the second input signal 167 of FIG. 1.

If, at block 606, the power switching circuit 102 determines that the low-side switch is not transitioning to the OFF state, control returns to block 602 to obtain another current measurement associated with the power switching circuit 102. If, at block 606, the power switching circuit 102 determines that the low-side switch is transitioning to the OFF state, then, at block 608, the power switching circuit 102 adjusts a transition rate of a high-side switch. For example, the gate driver controller 132 may decrease the turn-off rate of the first transistor 106. In such examples, the gate driver controller 132 can generate and transmit a low signal to one or more of the gate driver segments 138a-c of the first gate driver 134 via the first turn-off segment disable bus 162 to turn off one(s) of the second logic gates 208, 210, 212 of FIG. 2A. By reducing the quantity of gate driver segments 138a-c of the first gate driver 134 that are turned on, the gate driver controller 132 can reduce the turn-off rate of the first transistor 106 by increasing the impedance to the first transistor 106. In response to adjusting the transition rate of the high-side switch, the machine readable instructions 600 of FIG. 6 conclude.

If, at block 604, the power switching circuit 102 determines that the current measurement does not satisfy the first current threshold, control proceeds to block 610 to determine whether the current measurement satisfies a second current threshold. For example, the second comparator 146 of FIG. 1 may compare the voltage 145 to the second current threshold 150 and generate the second trip signal 142 based on the comparison. In such examples, the first comparator 144 can generate a high signal for the first trip signal 140 when the voltage 145 is greater than the first trip signal 140.

If, at block 610, the power switching circuit 102 determines that the current measurement does not satisfy the second current threshold, control returns to block 602 to obtain another current measurement associated with the power switching circuit 102. If, at block 610, the power switching circuit 102 determines that the current measurement satisfies the second current threshold, then, at block 612, the power switching circuit 102 determines whether the low-side switch is transitioning to the OFF state. For example, the gate driver controller 132 may determine that the second transistor 108 of FIG. 1 is transitioning to the OFF state based on generating a high signal for the second input signal 167 of FIG. 1.

If, at block 612, the power switching circuit 102 determines that the low-side switch is not transitioning to the OFF state, control returns to block 602 to obtain another current measurement associated with the power switching circuit 102. If, at block 612, the power switching circuit 102 determines that the low-side switch is transitioning to the OFF state, then, at block 614, the power switching circuit 102 adjusts a transition rate of the low-side switch. For example, the gate driver controller 132 may decrease the turn-on rate of the second transistor 108. In such examples, the gate driver controller 132 can generate and transmit a low signal to one or more of the gate driver segments 138a-c of the second gate driver 136 via the second turn-on segment disable bus 160 to turn off one(s) of the first logic gates 202, 204, 206 of FIG. 2A. By reducing the quantity of gate driver segments 138a-c of the second gate driver 136 that are turned on, the gate driver controller 132 can reduce the turn-on rate of the second transistor 108 by increasing the impedance to the second transistor 108. In response to adjusting the transition rate of the low-side switch, the machine readable instructions 600 of FIG. 6 conclude.

FIGS. 7A-7B are flowcharts representative of example machine readable instructions 700 which may be executed to implement the gate driver controller 132 of FIGS. 1-2 and 5 to control and/or otherwise manage switching speeds of the first transistor 106 and the second transistor 108 of FIG. 1. The machine readable instructions 700 of FIGS. 7A-7B begin at block 702, at which the gate driver controller 132 obtains input signal(s). For example, the input interface 510 (FIG. 5) may obtain the first trip signal 140, the second trip signal 142, and/or the PWM inputs 152 of FIG. 1.

At block 704, the gate driver controller 132 determines whether a first trip signal indicates sensed current is greater than a positive current threshold. For example, the input interface 510 may determine that a received high signal for the first trip signal 140 indicates that the voltage 145 is greater than the first current threshold 148. In other examples, the input interface 510 may determine that a received low signal for the first trip signal 140 indicates that the voltage 145 is less than the first current threshold 148.

If, at block 704, the gate driver controller 132 determines that the first trip signal indicates that the sensed current is not greater than the positive current threshold, control proceeds to block 714 to determine whether a low-side switch is transitioning to the OFF state. If, at block 704, the gate driver controller 132 determines that the first trip signal indicates that the sensed current is greater than the positive current threshold, then, at block 706, the gate driver controller 132 determines whether the low-side switch is transitioning to the OFF state. For example, the control signal generator 530 (FIG. 5) may determine that the second transistor 108 of FIG. 1 is transitioning to the OFF state based on the control signal generator 530 generating a high signal for the second input signal 167 of FIG. 1.

If, at block 706, the gate driver controller 132 determines that the low-side switch is not transitioning to the OFF state, control returns to block 702 to obtain the input signal(s). If, at block 706, the gate driver controller 132 determines that the low-side switch is transitioning to the OFF state, then, at block 708, the gate driver controller 132 asserts a latched positive current trip signal high. For example, the control signal generator 530 may assert the first latched trip signal 302 of FIG. 3 high.

In response to asserting the latched positive current trip signal high at block 708, the gate driver controller 132 determines gate driver segment(s) to be selected at block 710. For example, the gate segment determiner 520 (FIG. 5) may select the first gate driver segment 138a of the first gate driver 134.

At block 712, the gate driver controller 132 generates control signal(s) to disable the selected gate driver segment(s) to reduce a turn-off rate of the high-side switch. For example, the control signal generator 530 may generate and transmit a low signal on the first turn-off segment disable bus 162 to the first AND logic gate 208 of FIG. 2A to turn off the first N-channel MOSFET 220 of FIG. 2A. In such examples, the control signal generator 530 can increase the impedance associated with the first gate control signal 168 to reduce the turn-off rate of the first transistor 106.

At block 714, the gate driver controller 132 determines whether the low-side switch is transitioning to the OFF state. For example, the control signal generator 530 may determine that the second transistor 108 of FIG. 1 is transitioning to the OFF state based on the control signal generator 530 generating a high signal for the second input signal 167 of FIG. 1.

If, at block 714, the gate driver controller 132 determines that the low-side switch is not transitioning to the OFF state, control returns to block 702 to obtain the input signal(s). If, at block 714, the gate driver controller 132 determines that the low-side switch is transitioning to the OFF state, then, at block 716, the gate driver controller 132 asserts the latched positive current trip signal low. For example, the control signal generator 530 may assert the first latched trip signal 302 low.

In response to asserting the latched positive current trip signal low at block 716, the gate driver controller 132 generates control signal(s) to restore the turn-off rate of the high-side switch at block 718. For example, the control signal generator 530 may generate and transmit a high signal on the first turn-off segment disable bus 162 to the first AND logic gate 208 of FIG. 2A to turn on the first N-channel MOSFET 220 of FIG. 2A. In such examples, the control signal generator 530 can decrease the impedance associated with the first gate control signal 168 to increase and/or otherwise restore the turn-off rate of the first transistor 106.

In response to generating the control signal(s) to restore the turn-off rate of the high-side switch at block 718, the gate driver controller 132 determines whether to continue monitoring the power switching circuit 102 at block 720. If, at block 720, the gate driver controller 132 determines to continue monitoring the power switching circuit 102, control returns to block 702 to obtain the input signal(s), otherwise the machine readable instructions 700 of FIGS. 7A-7B conclude.

Additionally or alternatively, at block 722, the gate driver controller 132 determines whether a second trip signal indicates sensed current is less than a negative current threshold. For example, the input interface 510 may determine that a received high signal for the second trip signal 142 indicates that the voltage 145 is less than the second current threshold 150. In other examples, the input interface 510 may determine that a received low signal for the second trip signal 142 indicates that the voltage 145 is greater than the second current threshold 150.

If, at block 722, the gate driver controller 132 determines that the second trip signal indicates that the sensed current is not less than the negative current threshold, control proceeds to block 732 to determine whether the low-side switch is transitioning to the OFF state. If, at block 722, the gate driver controller 132 determines that the second trip signal indicates that the sensed current is less than the negative current threshold, then, at block 724, the gate driver controller 132 determines whether the low-side switch is transitioning to the OFF state. For example, the control signal generator 530 may determine that the second transistor 108 of FIG. 1 is transitioning to the OFF state based on the control signal generator 530 generating a high signal for the second input signal 167 of FIG. 1.

If, at block 724, the gate driver controller 132 determines that the low-side switch is not transitioning to the OFF state, control returns to block 702 to obtain the input signal(s). If, at block 724, the gate driver controller 132 determines that the low-side switch is transitioning to the OFF state, then, at block 726, the gate driver controller 132 asserts a latched negative current trip signal high. For example, the control signal generator 530 may assert the second latched trip signal 402 of FIG. 4 high.

In response to asserting the latched negative current trip signal high at block 726, the gate driver controller 132 determines gate driver segment(s) to be selected at block 728. For example, the gate segment determiner 520 may select the first gate driver segment 138a of the second gate driver 136.

At block 730, the gate driver controller 132 generates control signal(s) to disable the selected gate driver segment(s) to reduce a turn-on rate of the low-side switch. For example, the control signal generator 530 may generate and transmit a high signal on the second turn-on segment disable bus 160 to the first OR logic gate 202 of FIG. 2A to turn off the first P-channel MOSFET 214 of FIG. 2A. In such examples, the control signal generator 530 can increase the impedance associated with the second gate control signal 170 to reduce the turn-on rate of the second transistor 108.

At block 732, the gate driver controller 132 determines whether the low-side switch is transitioning to the OFF state. For example, the control signal generator 530 may determine that the second transistor 108 is transitioning to the OFF state based on the control signal generator 530 generating a high signal for the second input signal 167 of FIG. 1.

If, at block 732, the gate driver controller 132 determines that the low-side switch is not transitioning to the OFF state, control returns to block 702 to obtain the input signal(s). If, at block 732, the gate driver controller 132 determines that the low-side switch is transitioning to the OFF state, then, at block 734, the gate driver controller 132 asserts the latched negative current trip signal low. For example, the control signal generator 530 may assert the second latched trip signal 402 low.

In response to asserting the latched negative current trip signal low at block 734, the gate driver controller 132 generates control signal(s) to restore the turn-on rate of the low-side switch at block 736. For example, the control signal generator 530 may generate and transmit a low signal on the second turn-on segment disable bus 160 to the first OR logic gate 202 of FIG. 2A to turn on the first P-channel MOSFET 214 of FIG. 2A. In such examples, the control signal generator 530 can decrease the impedance associated with the second gate control signal 170 to increase and/or otherwise restore the turn-on rate of the second transistor 108.

In response to generating the control signal(s) to restore the turn-on rate of the low-side switch at block 736, the gate driver controller 132 determines whether to continue monitoring the power switching circuit 102 at block 720. If, at block 720, the gate driver controller 132 determines to continue monitoring the power switching circuit 102, control returns to block 702 to obtain the input signal(s), otherwise the machine readable instructions 700 of FIGS. 7A-7B conclude.

FIG. 8 is a block diagram of an example processor platform 800 structured to execute the instructions of FIGS. 6-7B to implement the gate driver controller 132 of FIGS. 1-2 and 5. The processor platform 800 can be, for example, a server, a personal computer, a workstation, or any other type of computing device.

The processor platform 800 of the illustrated example includes a processor 812. The processor 812 of the illustrated example is hardware. For example, the processor 812 can be implemented by one or more integrated circuits, logic circuits, microprocessors, GPUs, DSPs, or controllers from any desired family or manufacturer. The hardware processor may be a semiconductor based (e.g., silicon based) device. In this example, the processor 812 implements the input interface 510, the gate segment determiner 520, and the control signal generator 530 of FIG. 5.

The processing platform 800 of the illustrated example includes the gate driver(s) 134, 136 of FIGS. 1 and 2A and an example power converter 834. For example, the processor 812 may adjust an operation of the gate driver(s) 134, 136 to adjust an operation of the power converter 834. The example power converter 834 of FIG. 8 provides power to the processor 812. For example, the power converter 834 may be a buck converter, a boost converter, a buck-boost converter, or any other type of power converter. Additionally or alternatively, the processor platform 800 may include more than one power converter 834 to power one or more components of the processing platform 800. Accordingly, the processor 812 may adjust an operation of the additional power converters 834 using at least one of the input interface 510, the gate segment determiner 520, or the control signal generator 530.

The processor 812 of the illustrated example includes a local memory 813 (e.g., a cache). The processor 812 of the illustrated example is in communication with a main memory including a volatile memory 814 and a non-volatile memory 816 via a bus 818. The volatile memory 814 may be implemented by Synchronous Dynamic Random Access Memory (SDRAM), Dynamic Random Access Memory (DRAM), RAMBUS Dynamic Random Access Memory (RDRAM), and/or any other type of random access memory device. The non-volatile memory 816 may be implemented by flash memory and/or any other desired type of memory device. Access to the main memory 814, 816 is controlled by a memory controller.

The processor platform 800 of the illustrated example also includes an interface circuit 820. The interface circuit 820 may be implemented by any type of interface standard, such as an Ethernet interface, a universal serial bus (USB), a Bluetooth interface, a near field communication (NFC) interface, and/or a PCI express interface.

In the illustrated example, one or more input devices 822 are connected to the interface circuit 820. The input device(s) 822 permit(s) a user to enter data and/or commands into the processor 812. The input device(s) 822 can be implemented by, for example, an audio sensor, a microphone, a camera (still or video), a keyboard, a button, a mouse, a touchscreen, a track-pad, a trackball, an isopoint device, and/or a voice recognition system.

One or more output devices 824 are also connected to the interface circuit 820 of the illustrated example. The output devices 824 can be implemented, for example, by display devices (e.g., a light emitting diode (LED), an organic light emitting diode (OLED), a liquid crystal display (LCD), a cathode ray tube display (CRT), an in-place switching (IPS) display, a touchscreen, etc.), a tactile output device, a printer, and/or speaker. The interface circuit 820 of the illustrated example, thus, typically includes a graphics driver card, a graphics driver chip, and/or a graphics driver processor.

The interface circuit 820 of the illustrated example also includes a communication device such as a transmitter, a receiver, a transceiver, a modem, a residential gateway, a wireless access point, and/or a network interface to facilitate exchange of data with external machines (e.g., computing devices of any kind) via a network 826. The communication can be via, for example, an Ethernet connection, a digital subscriber line (DSL) connection, a telephone line connection, a coaxial cable system, a satellite system, a line-of-site wireless system, a cellular telephone system, etc.

The processor platform 800 of the illustrated example also includes one or more mass storage devices 828 for storing software and/or data. Examples of such mass storage devices 828 include floppy disk drives, hard drive disks, compact disk drives, Blu-ray disk drives, redundant array of independent disks (RAID) systems, and digital versatile disk (DVD) drives. In this example, the one or more mass storage devices 828 includes the example database 540 of FIG. 5.

The machine executable instructions 832 of FIGS. 6-7B may be stored in the mass storage device 828, in the volatile memory 814, in the non-volatile memory 816, and/or on a removable non-transitory computer readable storage medium such as a CD or DVD.

From the foregoing, it will be appreciated that example systems, methods, apparatus and articles of manufacture have been disclosed that dynamically adjust switching speeds of switching devices. Examples disclosed herein detect a power switching circuit parameter such as the current being handled by one or more switches for every switching event. Based on the detected current, examples disclosed herein dynamically adjust an output impedance of one or more gate drivers to a pre-determined level to control the speed of switch transition that improves and/or otherwise optimizes power efficiency with respect to switching stress. Examples disclosed herein improves the safety of switch operation and the reliability of the switches by adjusting and/or otherwise managing the transition rate, the transition time, etc., of the switches based on the polarity as well as the magnitude of the detected current. Examples disclosed herein improve the reliability and safe operation of the switches by detecting the current at every switching event and adjusting the transition rate, the transition time, etc., before the next switching transition to avoid high-stress events even for a (relatively) short duration.

The following pertain to further examples disclosed herein.

Example 1 includes a power switching system comprising a gate driver circuit including gate driver segments to adjust a transition time of a switch from a first time to a second time in response to a segment control signal, the transition time corresponding to a time to change a state of the switch, and a controller to obtain a first trip signal to indicate that a voltage exceeds a first threshold, obtain a second trip signal to indicate that the voltage is less than a second threshold, and transmit the segment control signal to the gate driver circuit when the switch is to change state and when the voltage exceeds the first threshold or is less than the second threshold.

Example 2 includes the power switching system of example 1, further including a first comparator to compare the voltage to the first threshold and assert the first trip signal when the voltage exceeds the first threshold, and a second comparator to compare the voltage to the second threshold and assert the second trip signal when the voltage is less than the second threshold.

Example 3 includes the power switching system of example 1, wherein a first gate driver segment of the gate driver segments includes a first transistor including a first gate and a first drain, a second transistor including a second gate and a second drain, the second drain coupled to the first drain, an and logic gate coupled to the first gate, the and logic gate to be coupled to the controller via a first bus, and an or logic gate coupled to the second gate, the or logic gate to be coupled to the controller via a second bus different from the first bus.

Example 4 includes the power switching system of example 3, wherein the first transistor is a P-channel metal oxide semiconductor field effect transistor (MOSFET) and the second transistor is a N-channel MOSFET.

Example 5 includes the power switching system of example 4, wherein the segment control signal is a first segment control signal, and the controller is to adjust the transition time by changing an output impedance of the gate driver circuit by transmitting the first segment control signal on the first bus to the or logic gate to enable the or logic gate to switch off the P-channel MOSFET, and transmitting a second segment control signal on the second bus to the and logic gate to enable the and logic gate to switch on the N-channel MOSFET.

Example 6 includes the power switching system of example 4, wherein the controller is to adjust the transition time by changing an output impedance of the gate driver circuit by disabling the or logic gate to switch on the P-channel MOSFET, and disabling the and logic gate to switch off the N-channel MOSFET.

Example 7 includes the power switching system of example 1, wherein the controller is to direct the gate driver circuit to adjust the transition time from the second time to the first time when the switch is to change state and when the voltage does not exceed the first threshold or is more than the second threshold.

Example 8 includes a power switching circuit comprising a gate driver circuit including gate driver segments, the gate driver segments including a first gate driver segment and a second gate driver segment, the first gate driver segment including a first transistor including a first gate and a first drain, a second transistor including a second gate and a second drain, the second drain coupled to the first drain, an and logic gate coupled to the first gate, and an or logic gate coupled to the second gate.

Example 9 includes the power switching circuit of example 8, wherein the first gate driver segment has a first output and the second gate driver segment has a second output coupled to the first output, and further including a third gate driver segment having a third output, the third output coupled to the first output and the second output.

Example 10 includes the power switching circuit of example 8, wherein the gate driver circuit is a first gate driver circuit, and further including a second gate driver circuit, and a controller coupled to the first gate driver circuit and the second gate driver circuit.

Example 11 includes the power switching circuit of example 10, wherein the controller is coupled to the first gate driver circuit via a first bus and a second bus, the first bus different from the second bus.

Example 12 includes the power switching circuit of example 11, wherein the controller is coupled to the and logic gate via a first connection of the first bus and is coupled to the or logic gate via a first connection of the second bus.

Example 13 includes the power switching circuit of example 12, wherein the and logic gate is a first and logic gate and the or logic gate is a first or logic gate, and further including a second and logic gate coupled to the controller via a second connection of the first bus, the second connection of the first bus different from the first connection of the first bus, and a second or logic gate coupled to the controller via a second connection of the second bus, the second connection of the second bus different from the first connection of the second bus.

Example 14 includes the power switching circuit of example 8, wherein the gate driver circuit is a first gate driver circuit, and further including a second gate driver circuit, a controller coupled to the first gate driver circuit and the second gate driver circuit, a current sensor, a first comparator coupled to the current sensor and the controller, and a second comparator coupled to the current sensor and the controller.

Example 15 includes a method for switching power in a circuit, the method comprising obtaining a measurement of current flowing through a transistor, and adjusting an impedance associated with a gate driver circuit based on the measurement, the gate driver circuit including gate driver segments, the adjusting including modifying an operation of a first gate driver segment of the gate driver segments.

Example 16 includes the method of example 15, further including determining whether the measurement satisfies a current threshold, in response to the measurement satisfying the current threshold, generating a trip signal, and adjusting the impedance to adjust a transition time of a transistor electrically in circuit with the gate driver circuit based on the trip signal and when the transistor is to change state.

Example 17 includes the method of example 16, wherein the current threshold is a first current threshold, the trip signal is a first trip signal, and the transition is a first transistor, and further including determining whether the measurement satisfies a second current threshold, in response to the measurement satisfying the second current threshold, generating a second trip signal, and adjusting the impedance to adjust the transition time of a second transistor based on the second trip signal and when the second transistor is to change state.

Example 18 includes the method of example 15, wherein adjusting the impedance is to adjust a transition time of a transistor electrically in circuit with the gate driver circuit from a first transition time to a second transition time, the second transition time slower than the first transition time.

Example 19 includes the method of example 15, wherein the transistor is a low-side transistor, the gate driver circuit is a second gate driver circuit, the second gate driver circuit is coupled to the low-side transistor, the low-side transistor is coupled to a high-side transistor, the high-side transistor is coupled to a first gate driver circuit, and further including transmitting a high signal as an input signal to the first gate driver circuit, transmitting a high signal to a first logic gate included in a first gate driver segment of the first gate driver circuit to turn on a first transistor, transmitting a low signal to a second logic gate included in a second gate driver segment of the first gate driver circuit to turn off a second transistor, the first gate driver segment coupled to the second gate driver segment, and adjusting a transition time of the high-side transistor by reducing a turn-off rate of the high-side transistor based on the second transistor being turned off

Example 20 includes the method of example 15, wherein the transistor is a low-side transistor, the gate driver circuit is a second gate driver circuit, the second gate driver circuit is coupled to the low-side transistor, the low-side transistor is coupled to a high-side transistor, the high-side transistor is coupled to a first gate driver circuit, and further including transmitting a low signal as an input signal to the second gate driver circuit, transmitting a low signal to a first logic gate included in a first gate driver segment of the second gate driver circuit to turn on a first transistor, transmitting a high signal to a second logic gate included in a second gate driver segment of the second gate driver circuit to turn off a second transistor, the first gate driver segment coupled to the second gate driver segment, and adjusting a transition time of the low-side transistor by reducing a turn-on rate of the low-side transistor based on the second transistor being turned off

Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. A power switching system comprising:
a gate driver circuit including gate driver segments to adjust a transition time of a switch from a first time to a second time in response to a segment control signal, the transition time corresponding to a time to change a state of the switch; and
a controller to:
obtain a first trip signal to indicate that a voltage exceeds a first threshold;
obtain a second trip signal to indicate that the voltage is less than a second threshold; and
transmit the segment control signal to the gate driver circuit when the switch is to change state and when the voltage exceeds the first threshold or is less than the second threshold.

2. The power switching system of claim 1, further including:
a first comparator to compare the voltage to the first threshold and assert the first trip signal when the voltage exceeds the first threshold; and
a second comparator to compare the voltage to the second threshold and assert the second trip signal when the voltage is less than the second threshold.

3. The power switching system of claim 1, wherein a first gate driver segment of the gate driver segments includes:
a first transistor including a first gate and a first drain;
a second transistor including a second gate and a second drain, the second drain coupled to the first drain;
an AND logic gate coupled to the first gate, the AND logic gate to be coupled to the controller via a first bus; and
an OR logic gate coupled to the second gate, the OR logic gate to be coupled to the controller via a second bus different from the first bus.

4. The power switching system of claim 3, wherein the first transistor is a P-channel metal oxide semiconductor field effect transistor (MOSFET) and the second transistor is a N-channel MOSFET.

5. The power switching system of claim 4, wherein the segment control signal is a first segment control signal, and the controller is to adjust the transition time by changing an output impedance of the gate driver circuit by:
transmitting the first segment control signal on the first bus to the OR logic gate to enable the OR logic gate to switch off the P-channel MOSFET; and
transmitting a second segment control signal on the second bus to the AND logic gate to enable the AND logic gate to switch on the N-channel MOSFET.

6. The power switching system of claim 4, wherein the controller is to adjust the transition time by changing an output impedance of the gate driver circuit by:
disabling the OR logic gate to switch on the P-channel MOSFET; and
disabling the AND logic gate to switch off the N-channel MOSFET.

7. The power switching system of claim 1, wherein the controller is to direct the gate driver circuit to adjust the transition time from the second time to the first time when the switch is to change state and when the voltage does not exceed the first threshold or is more than the second threshold.

8. A power switching circuit comprising:
a gate driver circuit including gate driver segments, the gate driver segments including a first gate driver segment and a second gate driver segment, the first gate driver segment including:
a first transistor including a first gate and a first drain;
a second transistor including a second gate and a second drain, the second drain coupled to the first drain;
an AND logic gate coupled to the first gate; and
an OR logic gate coupled to the second gate.

9. The power switching circuit of claim 8, wherein the first gate driver segment has a first output and the second gate driver segment has a second output coupled to the first output, and further including a third gate driver segment having a third output, the third output coupled to the first output and the second output.

10. The power switching circuit of claim 8, wherein the gate driver circuit is a first gate driver circuit, and further including:
a second gate driver circuit; and
a controller coupled to the first gate driver circuit and the second gate driver circuit.

11. The power switching circuit of claim 10, wherein the controller is coupled to the first gate driver circuit via a first bus and a second bus, the first bus different from the second bus.

12. The power switching circuit of claim 11, wherein the controller is coupled to the AND logic gate via a first connection of the first bus and is coupled to the OR logic gate via a first connection of the second bus.

13. The power switching circuit of claim 12, wherein the AND logic gate is a first AND logic gate and the OR logic gate is a first OR logic gate, and further including:
a second AND logic gate coupled to the controller via a second connection of the first bus, the second connection of the first bus different from the first connection of the first bus; and
a second OR logic gate coupled to the controller via a second connection of the second bus, the second connection of the second bus different from the first connection of the second bus.

14. The power switching circuit of claim 8, wherein the gate driver circuit is a first gate driver circuit, and further including:
a second gate driver circuit;
a controller coupled to the first gate driver circuit and the second gate driver circuit;
a current sensor;
a first comparator coupled to the current sensor and the controller; and
a second comparator coupled to the current sensor and the controller.

15. A method for switching power in a circuit, the method comprising:
obtaining a measurement of current flowing through a transistor;
adjusting an impedance associated with a gate driver circuit based on the measurement, the gate driver circuit including gate driver segments, the adjusting including modifying an operation of a first gate driver segment of the gate driver segments;
determing whether the measurement satisfies a current threshold;
in response to the measurement satisfying the current threshold, generating a trip signal; and
adjusting the impedance to adjust a trasition time of a trasistor electrically in circuit with the gate driver circuit based on the trip signal and when the transistor is to change state.

16. (canceled)

17. The method of claim 15, wherein the current threshold is a first current
threshold, the trip signal is a first trip signal, and the transition is a first transistor, and further including:
determining whether the measurement satisfies a second current threshold;
in response to the measurement satisfying the second current threshold, generating a second trip signal; and
adjusting the impedance to adjust the transition time of a second transistor based on the second trip signal and when the second transistor is to change state.

18. The method of claim 15, wherein adjusting the impedance is to adjust a transition time of a transistor electrically in circuit with the gate driver circuit from a first transition time to a second transition time, the second transition time slower than the first transition time.

19. The method of claim 15, wherein the transistor is a low-side transistor, the gate driver circuit is a second gate driver circuit, the second gate driver circuit is coupled to the low-side transistor, the low-side transistor is coupled to a high-side transistor, the high-side transistor is coupled to a first gate driver circuit, and further including:
transmitting a high signal as an input signal to the first gate driver circuit;
transmitting a high signal to a first logic gate included in a first gate driver segment of the first gate driver circuit to turn on a first transistor;
transmitting a low signal to a second logic gate included in a second gate driver segment of the first gate driver circuit to turn off a second transistor, the first gate driver segment coupled to the second gate driver segment; and
adjusting a transition time of the high-side transistor by reducing a turn-off rate of the high-side transistor based on the second transistor being turned off

20. The method of claim 15, wherein the transistor is a low-side transistor, the gate driver circuit is a second gate driver circuit, the second gate driver circuit is coupled to the low-side transistor, the low-side transistor is coupled to a high-side transistor, the high-side transistor is coupled to a first gate driver circuit, and further including:
transmitting a low signal as an input signal to the second gate driver circuit;
transmitting a low signal to a first logic gate included in a first gate driver segment of the second gate driver circuit to turn on a first transistor;
transmitting a high signal to a second logic gate included in a second gate driver segment of the second gate driver circuit to turn off a second transistor, the first gate driver segment coupled to the second gate driver segment; and
adjusting a transition time of the low-side transistor by reducing a turn-on rate of the low-side transistor based on the second transistor being turned off.
